(19) United States
(12) Patent Application Publication
(10) Pub. No.: US 2014/0026933 A1
(43) Pub. Date: Jan. 30, 2014

(54) THERMOELECTRIC APPARATUS FOR GENERATING ELECTRIC ENERGY FROM A THERMAL ENERGY SOURCE

(71) Applicant: Flamestower, Inc., East Palo Alto, CA (US)

(72) Inventors: Adam KELL, Palo Alto, CA (US); Andrew Gordon BYRNES, East Palo Alto, CA (US)

(21) Appl. No.: 13/918,879

(22) Filed: Jun. 14, 2013

Related U.S. Application Data
(60) Provisional application No. 61/814,171, filed on Apr. 19, 2013.
(60) Provisional application No. 61/659,845, filed on Jun. 14, 2012.

(51) Int. Cl. H01L 35/32

(52) U.S. Cl. CPC H01L 35/32
USPC 136/205

(57) ABSTRACT

Apparatuses for converting heat energy into electrical energy are described. An example apparatus may include a thermoelectric generator (TEG) device and a heat sink component. The heat sink component can include a heat sink reservoir adapted for holding a heat transfer medium (e.g., a liquid). The TEG device includes a TEG module having a hot surface and a cold surface, the hot surface adapted to receive heat from the heat source. The TEG device may be coupled to the heat sink component in any suitable manner to reduce thermal resistance between the heat sink component and the cold surface of the TEG module. The heat sink component may be joined to the TEG device such that the heat sink liquid contacts the cold surface of the TEG module. The apparatus may further include a thermally-conductive member (TCM), which may be configured to transport heat to the TEG module.

### CROSS REFERENCE TO RELATED APPLICATIONS

This application claims the priority of U.S. provisional application Ser. No. 61,659,845 filed Jun. 14, 2012 and U.S. provisional application Ser. No. 61,814,171 filed Apr. 19, 2013, the entire contents of each of which is incorporated herein by this reference.

### TECHNICAL FIELD

This present disclosure relates to apparatuses and methods for converting thermal energy into electrical energy.

### BACKGROUND

Portable electronic devices such as laptops, tablets, e-readers, smart phones, MP3 players and the like, have become ubiquitous in our everyday lives enabling users to take their data (files, pictures, music, e-books, videos) on the go. Typically portable electronic devices of this kind are equipped with a rechargeable power source (e.g. rechargeable battery). In some instances and due to the portability of such electronic devices it may not always be possible or practicable to charge such electronic devices using grid power. Conventional power generation devices (e.g. combustion engine based and/or renewable distributed generators) may not be optimal for off-grid or in the wild charging of portable electronic devices because conventional power generation devices may include moving components making them more complex, less portable, expensive, and often having high parasitic loads to be suitable for low power generation. The examples described herein may address some or all of the shortcomings of conventional off-grid power generation devices.

### BRIEF DESCRIPTION OF THE DRAWINGS

A brief description of the drawings is provided below to facilitate understanding of the present disclosure. These drawings depict only several examples in accordance with the disclosure and are, therefore, not to be considered limiting of its scope. The disclosure will be described with additional specificity and detail through use of the accompanying drawings, in which:

FIG. 1 is an isometric view of a first embodiment of an apparatus according to the present disclosure,

FIG. 2 is a side view of the apparatus in FIG. 1,

FIG. 3 is a top view of the apparatus in FIG. 1,

FIG. 4 is a cross-sectional view of the apparatus in FIGS. 1-3 taken along the line 4-4 in FIG. 1,

FIG. 5 is a partial enlarged view of the cross-section in FIG. 4,

FIG. 6 is a simplified illustration of a TEG module according to the present disclosure,

FIGS. 7A-7C are plan and side views of an embodiment of a TEG module according to the present disclosure,

FIGS. 8A-8C are plan and side views of an alternate embodiment of a TEG module according to the present disclosure,

FIG. 9 is an illustration of another example of an interface between a TEG device and a heat sink component of an apparatus according to the present disclosure,

FIG. 10 is a circuit diagram of a power converter according to the present disclosure,

FIG. 11 is an isometric view of the apparatus in FIG. 1 shown in a first alternate configuration,

FIG. 12 is a side view of the apparatus in FIG. 11,

FIG. 13 is a top view of the apparatus in FIG. 11,

FIG. 14 is an isometric view of the apparatus in FIG. 1 shown in a second alternate configuration,

FIG. 15 is an isometric view of the apparatus in FIG. 1 shown in a third alternate configuration,

FIG. 16 is an illustration of apparatuses according to the present disclosure in a plurality of configurations for use with a plurality of different sources of thermal energy,

FIG. 17 is an illustration of an apparatus according to the present disclosure including a photovoltaic cell,

FIG. 18 is an isometric view of a second embodiment of an apparatus according to the present disclosure,

FIG. 19 is an isometric exploded view of the apparatus in FIG. 18,

FIG. 20 is a side view of the apparatus in FIG. 18,

FIG. 21 is a partial side exploded view of the apparatus in FIG. 18,

FIGS. 22A and 22B are isometric views of two embodiments of a thermally-conductive member (TCM) according to the present disclosure,

FIG. 23 is an isometric view of the apparatus in FIG. 18 shown in a first alternate configuration,

FIG. 24 is an isometric view of the apparatus in FIG. 18 shown in a second alternate configuration,

FIG. 25 is an isometric view of the apparatus in FIG. 18 shown in a third alternate configuration,

FIGS. 26-30 are top, bottom, back, side, and front views of the apparatus in FIG. 18 in a fourth alternate (e.g., compact or low-profile) configuration,

FIG. 31 is a block diagram of a modular system according to the present disclosure,

FIG. 32 is a bottom isometric view of a third embodiments of an apparatus according to the present disclosure

### DETAILED DESCRIPTION

In the following detailed description, reference is made to the accompanying drawings, which form a part hereof. In the drawings, similar symbols typically identify similar components, unless context dictates otherwise. The illustrative examples described in the detailed description and depicted in the drawings are not meant to be limiting. Other examples may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are implicitly contemplated herein.

Examples of apparatuses for converting heat energy into electrical energy, for example for providing electrical energy to a portable electronic device, are described. Apparatuses according to the present disclosure may include a thermoelectric generator (TEG) device, and a heat sink component. The TEG device may include a TEG module, also referred to herein as thermoelectric generator or thermoelectric device, which may include a first or hot surface or side and a second or cold surface or side, the hot surface of the TEG module adapted to receive heat from the heat source. The TEG device may be coupled to the heat sink component in any suitable manner so as to reduce or minimize thermal resistance between the heat sink component and the cold surface of the TEG module. The heat sink component may be implemented to utilize inexpensive materials as the heat transfer medium. For example, the heat sink component may include a container or reservoir (also referred to as heat sink), which is adapted to hold a liquid (e.g. water) therein. The liquid may serve as the heat transfer medium or heat sink to which heat is transferred for dissipation to the environment. The cold surface of the TEG module may be thermally coupled to the heat sink component in a manner which provides a low thermal resistance path between the TEG module and the heat sink component. For example, the heat sink component may be joined to the cold surface of the TEG module so that liquid in the reservoir engages the cold surface of the thermoelectric generator (e.g., TEG module), as will be further described. During operation, heat may be transported through the TEG module from the hot surface to the cold surface to generate electricity as will be further described. The TEG device and/or heat sink component may be further coupled to additional components configured to facilitate transporting heat to the hot surface of the TEG module. For examples, an optional thermally-conductive element may be used to transport heat from the heat source to the TEG module in some embodiments. In other examples, heat from the heat source may be directly applied to the hot surface of the TEG module. The apparatuses describes herein may be configured for portability and may have few, if any, moving parts e.g., for simplicity and ease of manufacture.

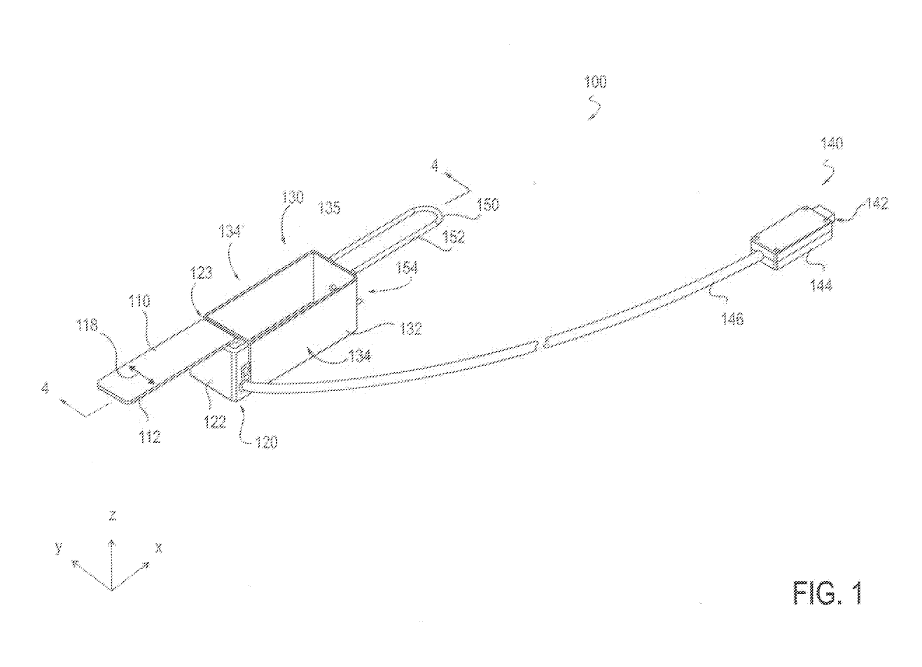

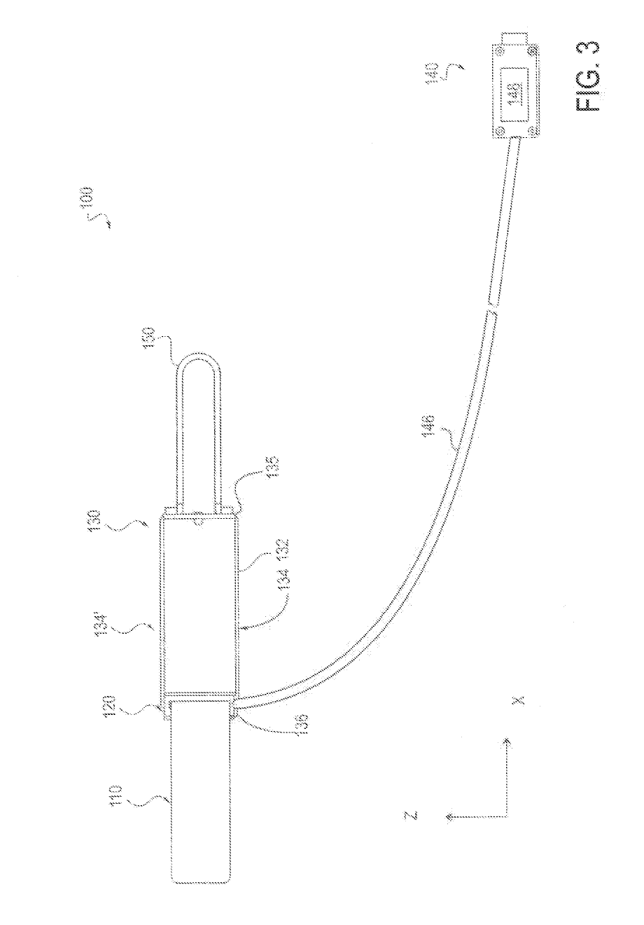

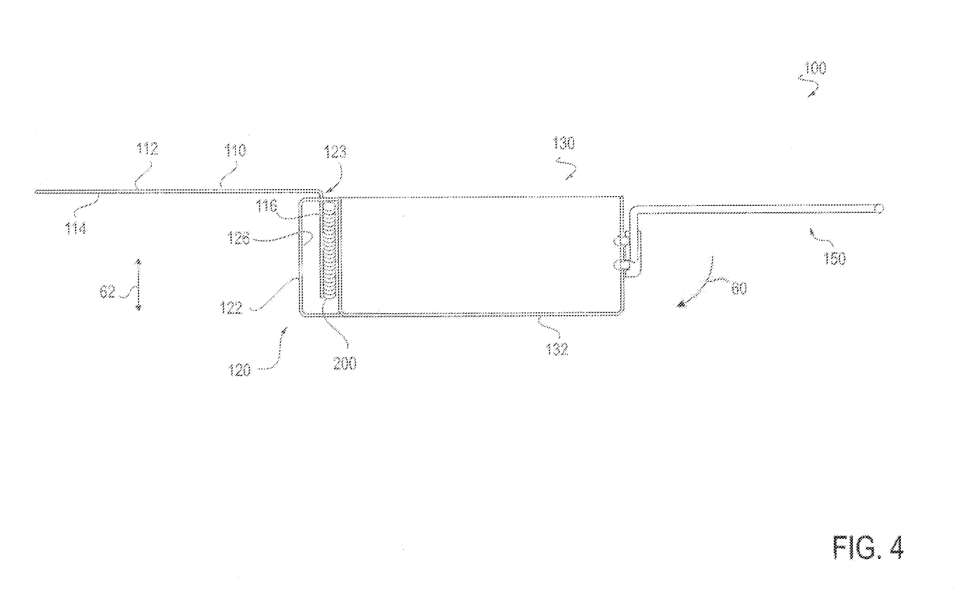

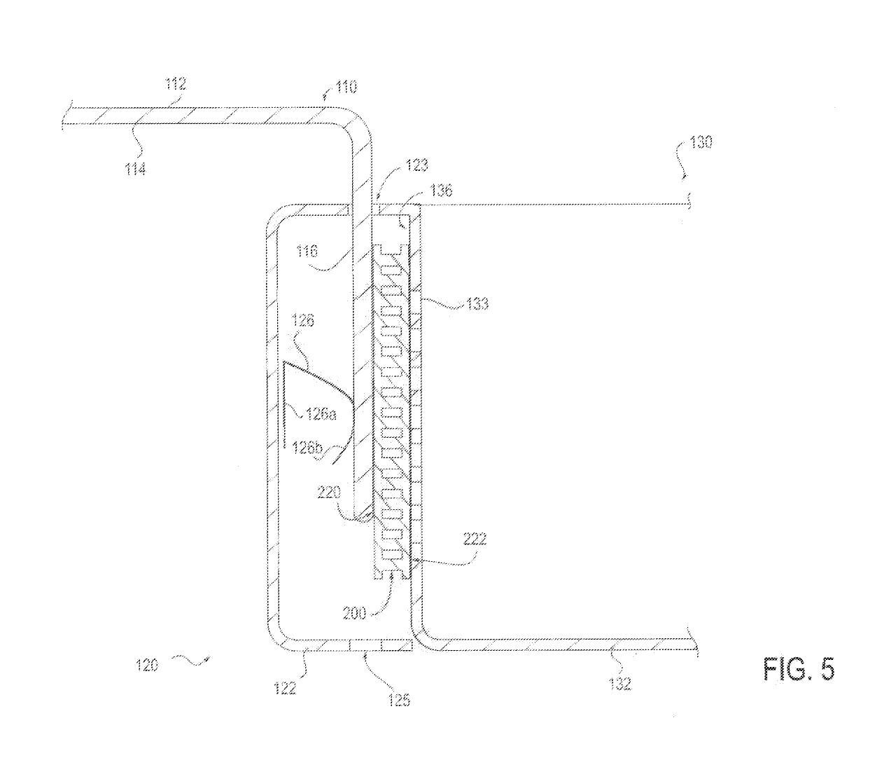

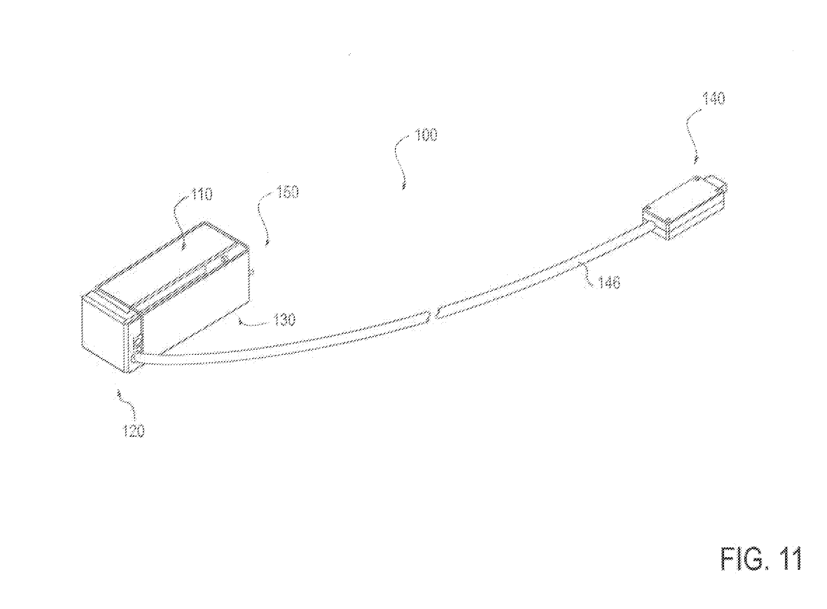

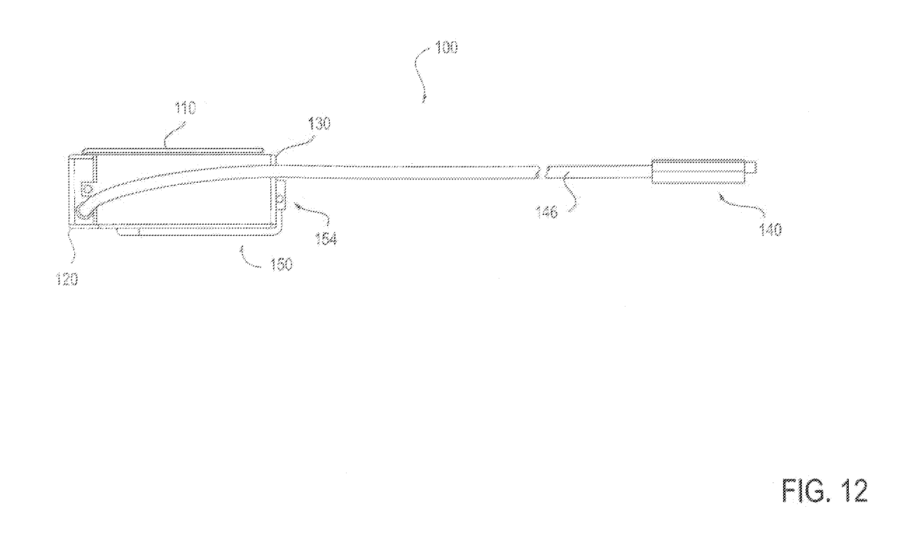

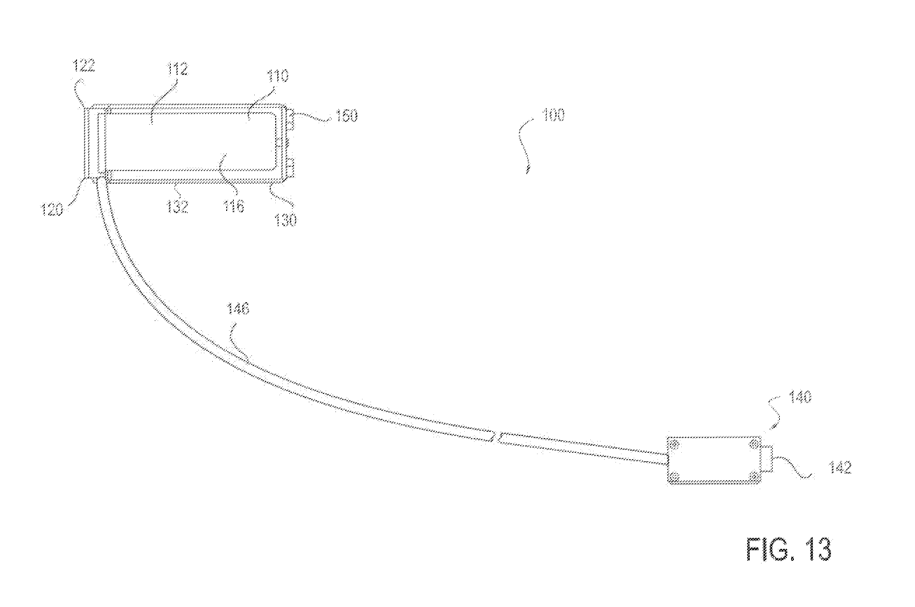

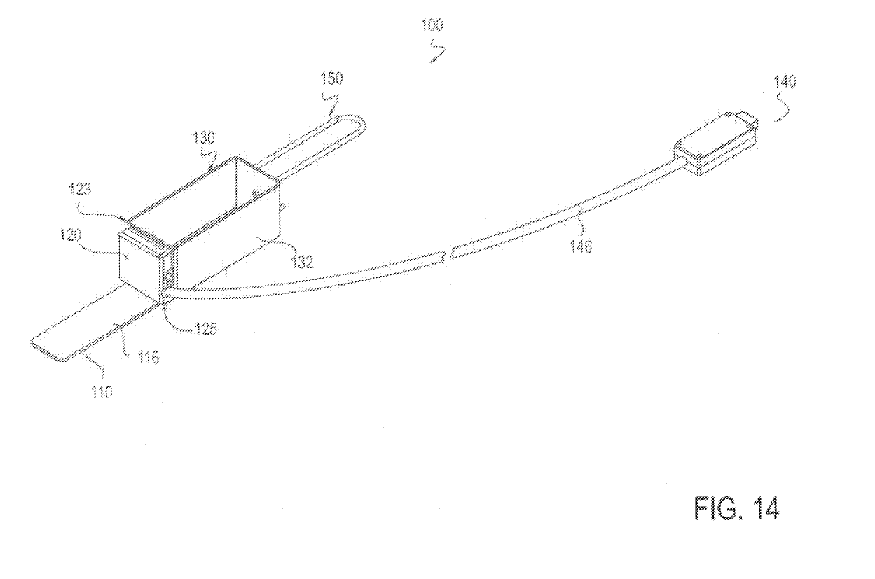

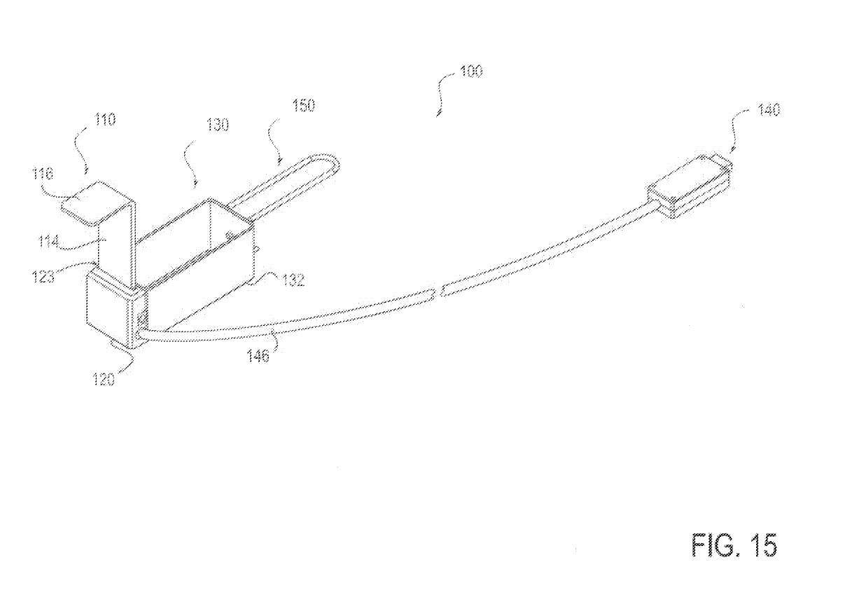

A portable apparatus 100 according to one embodiment of the present disclosure is depicted in FIGS. 1-5, and 11-15. FIGS. 1-3 show isometric, side and top views, respectively, of the apparatus 100 in a first open configuration. FIG. 4 shows a cross-sectional view along the line 4-4 in FIG. 3. FIG. 5 shows a partial detail view of the cross-sectional view of FIG. 4. FIGS. 11-13 show side and top views, respectively, of the apparatus 100 in a compact or collapsed configuration, e.g., for storage and/or transport. FIGS. 14 and 15 show other open or expanded configurations of the apparatus 100.

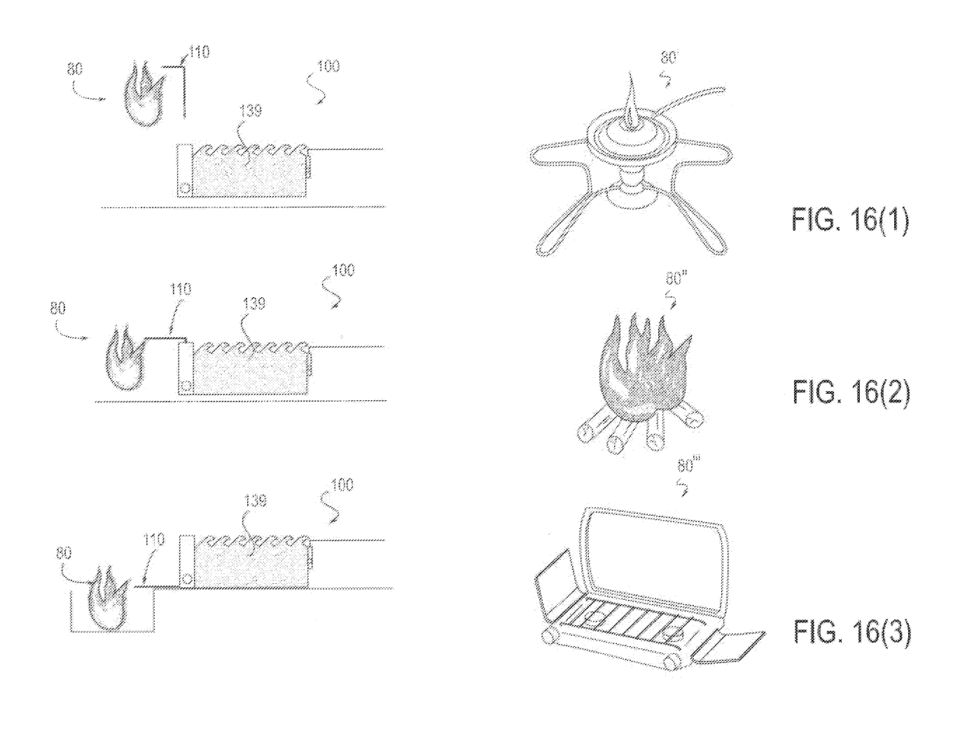

The apparatus 100 is a hand-held apparatus, which includes a thermally-conductive element 110, interchangeably referred to herein as thermally-conductive member (TCM) 110, a thermoelectric generator (TEG) device 120, and a heat sink component 130. The TEG device 120 may include a support structure that includes a retainer or housing 122 and one or more thermoelectric generator (TEG) modules 200, each of which may be adapted to convert heat energy to electrical energy, as will be further described. The retainer or housing 122 may include a socket or cavity for receiving a portion of the TCM and may include a retainer element, as will be further described, for urging the portion of the TCM against a surface of the TEG module. The heat sink component 110 may include a container or reservoir 132, which is adapted to hold a liquid (see 139 in FIG. 16) or other heat transfer medium. The liquid may be water, which can serve as a heat transfer medium for absorbing heat from the one or more TEG modules 200 and dissipating the absorbed heat to the environment. The heat sink component 110 may be attached to the TEG device 120 in any suitable manner to minimize thermal resistance between the heat sink component 110 and the TEG 120. In some examples, the heat sink component 110 and/or TEG device 120 are configured for direct engagement of the liquid with a surface of the TEG module, as will be further described. The apparatus may further include a power component 140, which may include a connector 142 for coupling to an electrical device (not shown) such that electricity generated by the TEG module 200 may be delivered to the electrical device.

The TCM 110 may be configured to conduct thermal energy from a heat source (e.g., a fire) towards the TEG module 200. The TCM may have virtually any shape as may be desired or suitable for a particular application. In some embodiments, the TCM may be implemented as a plate, a fin, a blade, or a tongue extending from the TEG device, for example as depicted in FIG. 1. The TCM may be a strip of metal or a metallic plate. In some examples, the TCM 110 may be a sheet of material, a rod or another extruded or elongate structure. The TCM 110 may be made from a thermally conductive material, such as metal. In some examples, the TCM 110 may be made from aluminum (e.g., anodized), steel, copper, or pyrolytic graphite. Composite or multi-layered materials may also be used, for example, the TCM may be made from a base material of aluminum with a coating of a different metallic material (e.g. copper). During use, the TCM may be provided in direct contact with the heat source (e.g., the tongue may be exposed to and/or touching an open flame) and heat from the heat source may be transported along the length of the TCM towards the TEG module.

As will be understood, the TCM 110 is configured to, among other things, channel or transport thermal energy from the heat source (e.g. an open flame) towards the TEG module 200. Generally, suitable materials for the TCM 110 may include materials with high thermal transport properties and low loss. In some examples, the TCM may be a heat pipe, which includes a working fluid suitable for the operating conditions (e.g., operational temperature range) of the TCM within a cavity between surfaces of the TCM. A heat pipe TCM may be advantageous as it may enable the TCM or tongue to extend a greater distance away from the TEG device, which may be referred to as “reach” of the apparatus, without adversely affecting thermal transport performance. An apparatus with a greater “reach” may be particularly advantageous for applications in which the flame source, for example, a camp fire or a “three-stone fire” that uses wood or charcoal as fuel, which may be less contained than other flame sources, such as a cooking stove.

In the example in FIG. 1, the TCM is implemented as an L-shaped element 112 having a first or long portion 114 and a second or short portion 116 extending orthogonal to each other. The first portion may have a first length and the second portion may have a second length different from the length of the first portion, that is the first length. In some embodiments, the TCM may be a monolithic member, and as such the portions 114 and 116 are made from a single block or sheet of material. The length of any of the portions 114 and/or 116 may be selected to suit the particular application. For example, the length of long portion 114 may be selected to enable placement of an end of the TCM in the flames of a fire, while mainlining other portions of the apparatus (e.g., the TEG device and/or heat sink component) some distance away from the fire. That is, in some examples, the length of the long portion 114 is selected to provide a desired “reach” of the apparatus as may be suited for a particular application. In some examples, a length of the long portion 114 of the TCM may substantially correspond to a length of the reservoir 132 along its longitudinal dimension, which may enable collapsing the apparatus 100 into a compact configuration for storage, as will be further described with reference to FIGS. 11-13. The length of the short portion 116 may in some examples substantially correspond to a length of the TEG device along the vertical direction, which may maximize contact area between the TCM and TEG module(s) in certain configurations. In a first example, the TCM 110 may be made of anodized aluminum with a width (e.g., 118) of about 2-6 cm and a length of about 10-15 cm. In one such embodiment, the long portion 114 may have a length of about 120 mm and the short portion 116 may have a length of about 45 mm. In a second example, the TCM 110 may have a length greater than 10-15 cm, which may facilitate use of the apparatus with larger heat sources. Thermal analysis tools (e.g., finite element modeling and analysis (FEA/FEM) techniques) can be utilized to optimize the length, shape, thickness, material properties and other design parameters of the TCM for the particular application and without departing from the scope of the present disclosure.

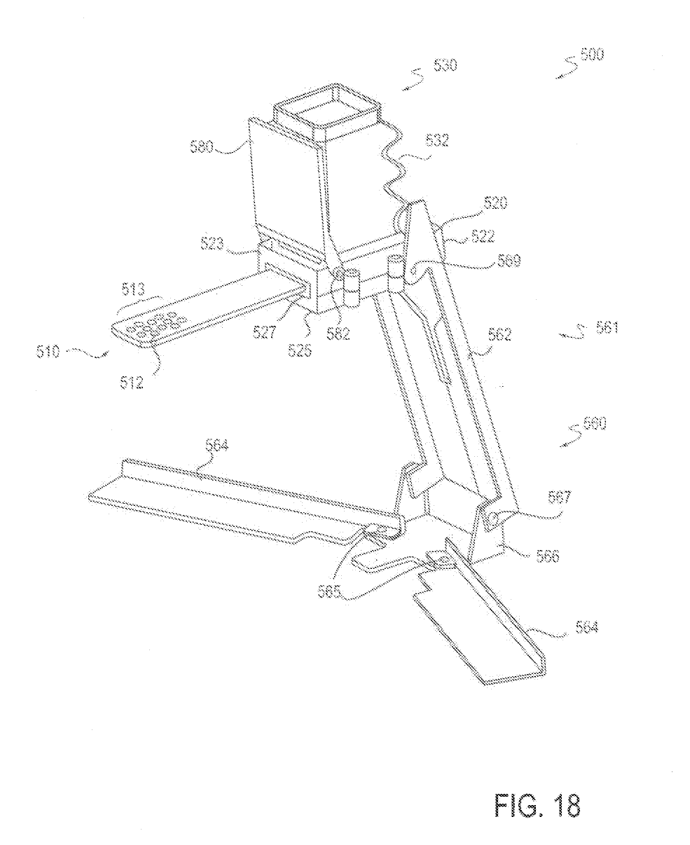

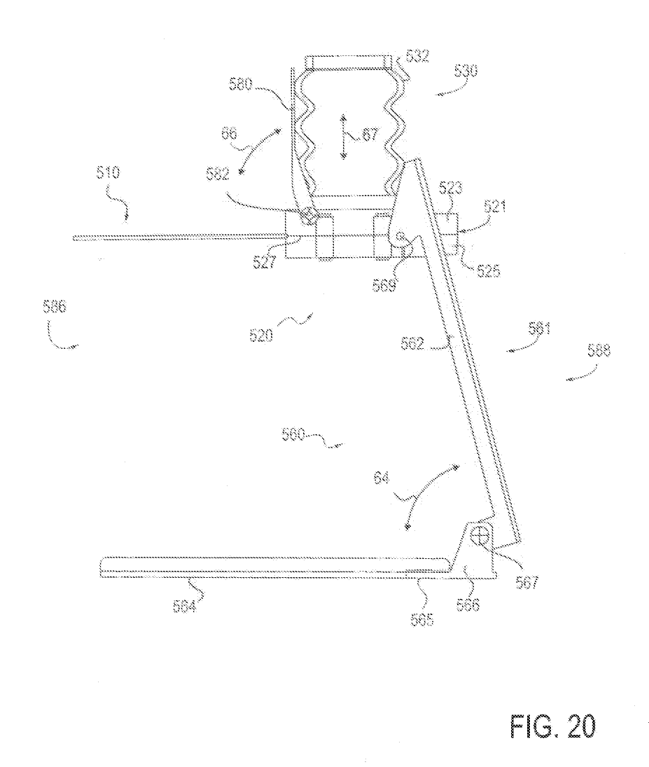

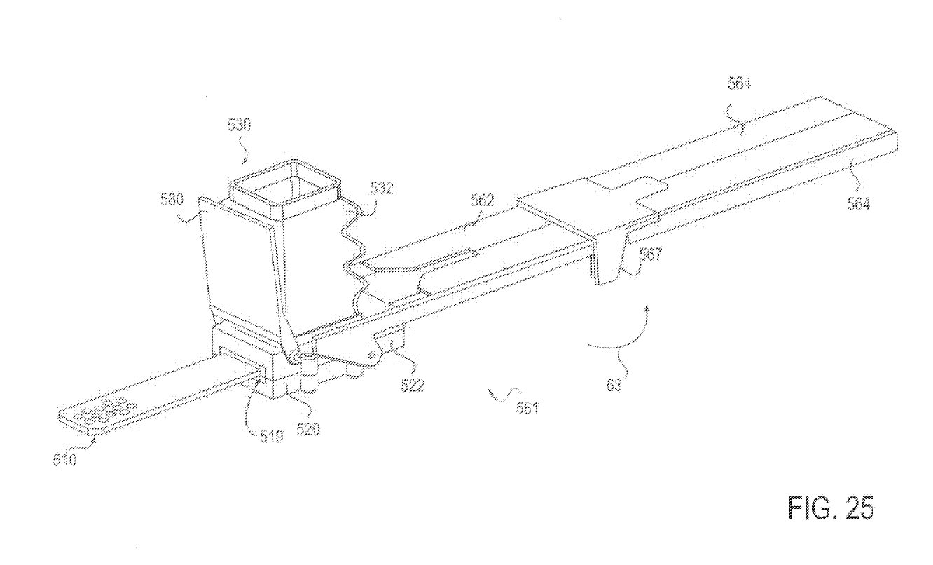

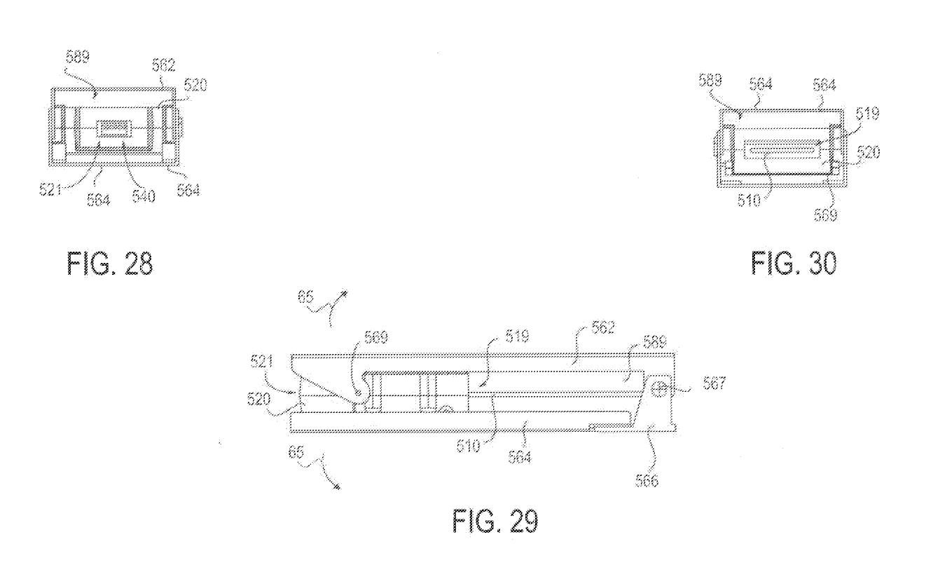

In some examples, the width 118 of the TCM may vary along the longitudinal direction (e.g., along the x-direction). For example, the TCM 110 may have a first width away from the TEG which is greater than a second width closer to the TEG thereby defining a larger surface area at the end of the TCM which is placed in contact with the flame. Such increased heated surface area may facilitate uniform temperature at the interface between the TCM 110 and the TEG module 200. In other embodiments, the TCM 100 may be a flat, planar element, as will be further described with reference to FIGS. 18-30. As will be understood, apparatuses according to the present disclosure may be configured for use with any one of a plurality of interchangeable TCMs. For example, a kit according to the present disclosure may include the apparatus 100 and a plurality of differently sized TCMs, each of which may be configured to be removably attached to the TEG device 120 for use with different types of heat sources.

As previously described, the TEG device 120 may include a retainer or housing 122 and a TEG module 200 (see FIGS. 4 and 5). For ease of explanation, a single TEG module is described and shown in the examples herein however it will be understood that any number of TEG modules may be used in apparatuses according to the present disclosure.

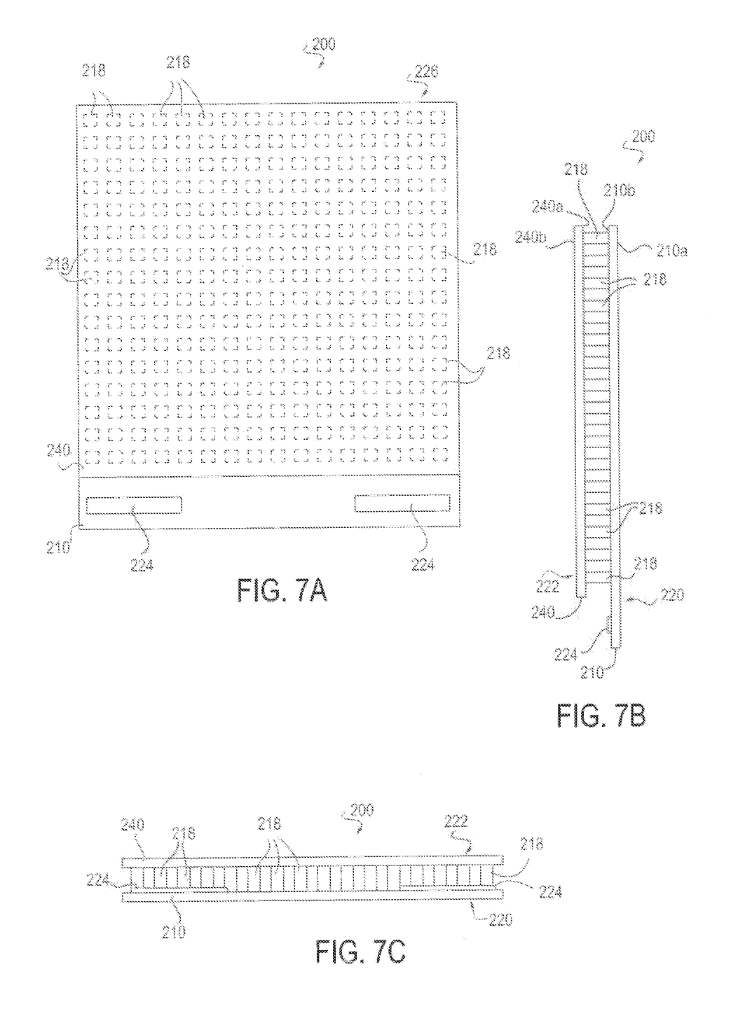

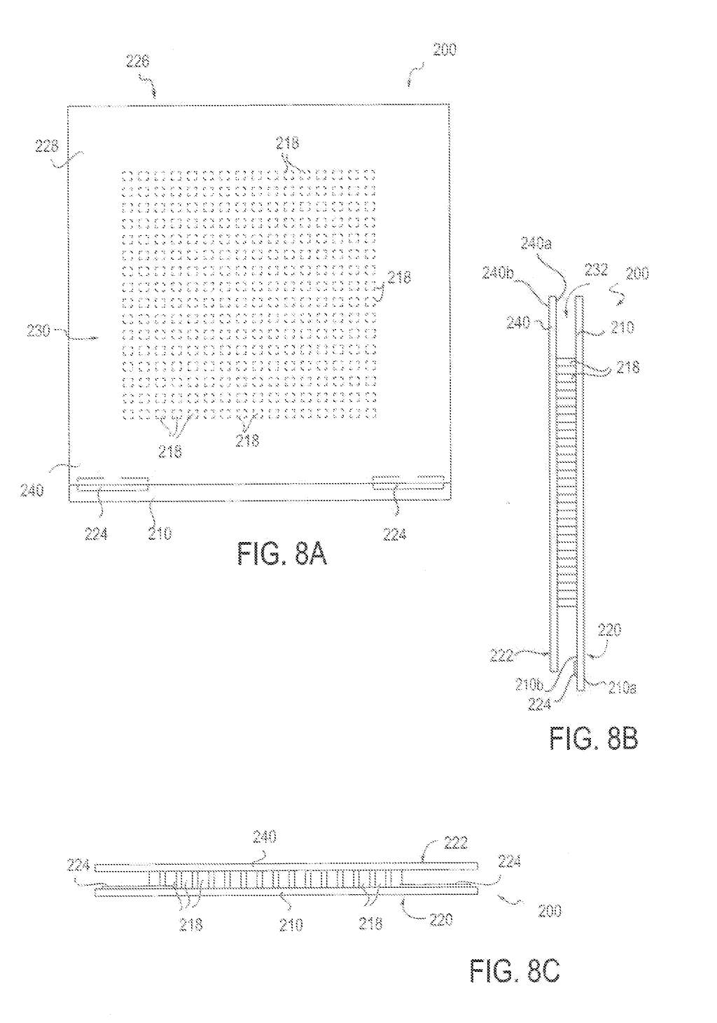

The housing 122 may at least partially enclose the TEG module 200. The TEG module 200 and correspondingly the housing 122 may have any form factor as may be desired or as may be suitable for a particular application. For example, the TEG module 200 may be generally rectangular in shape (see e.g., FIGS. 7-8). Correspondingly, the housing 122 in the embodiment depicted in FIGS. 1-15 has a substantially cuboid shape (e.g., a six-sided enclosure). In other examples, the TEG module may be circular, oval, or may be irregularly shaped as may be desired. The housing 122 may include a plurality of sidewalls 124 (e.g., top, bottom, front, back or rear, left, and right walls). The sidewalls 124 of the housing 122 define a cavity 121 within which the TEG module 200 is disposed. The housing 122 may be made from any suitable material, for example aluminum (e.g., aluminum sheet metal). In other examples, the housing 122 may be made, at least in part, from an insulating material such as a high temperature capable plastic or ceramic. The housing 122 may be configured to at least partially insulate the TEG module 200 from the heat source so as to maintain a desired temperature profile across the TEG module 200.

The TEG module 200 may include a first or hot surface 220 and a second or cold surface 222 (see FIG. 5). The hot surface 220 may be thermally coupled to the TCM 110 for transferring heat from the heat source to the hot surface 220. In some embodiments, the TCM 110 may be attached to the hot surface 220 of the TEG module in a manner which does not interfere with heat transfer. In some examples, the TCM may be adhered or bonded to the hot surface using a thermally conductive adhesive. Other known techniques for fusing or bonding the two components at the hot surface may be used. Mechanical fastening techniques may also be used, and thermal grease may be applied at the interface between the TCM and the TEG module to minimize thermal impedance at the interface. In further examples, the TCM may be pressed against the hot surface 220, e.g., using a compression member as will be further described with reference to FIG. 18-21.

In some embodiments, the TCM 130 may be removably engageable with the hot surface of the TEG module 200. For example, the apparatus 100 according to the embodiment in FIGS. 1-15 is configured for removable engagement of the TCM with the TEG module. The TCM 110 may be removably attached to the TEG device by inserting a portion of the TCM 110 in the housing 122 and maintaining the TCM in position against the TEG module by a retaining element 132, also referred to as TCM retainer, retainer element, or retainer 126. The retainer 126, which is disposed in the cavity 121, may be a spring-loaded member configured to urge the inserted portion of the TCM 130 against the hot surface 220 of the TEG module. The retainer 126 may be used to maintain the TCM in thermal contact, in some cases in direct physical contact, with the hot surface 220 so as to facilitate efficient heat transfer from the TCM to the TEG module. The retainer 126 may be configured to permit removal of the TCM 110 e.g., for storage and/or replacement.

The retainer 126 may be a spring having a flat portion 126a which rests against or is secured to the front wall of the housing 122, the spring further having a generally rounded or c-shaped portion 126b with a rounded apex which arranged towards the hot surface 220 of the TEG module. Prior to use and/or storage, the TCM 110 may be inserted into the cavity 121. Upon insertion, the retainer 126 (e.g., rounder portion 126b) may abut or press against the TCM thereby holding the TCM in place against the hot surface 220. The retainer or spring 126 may have a spring constant such that the retainer to apply a sufficiently large force against the TCM to maintain the TCM in direct physical contact with the hot surface 220. In some examples, the spring constant of the retainer is large enough to exert a pressure ranging between 1 psi and 300 psi. The retainer may be made, at least partially, from an insulating material to reduce or prevent heat transfer from the TCM to the retainer and subsequently to the housing 112. In some examples, at least a portion of the retainer e.g., the rounded portion 126b, may be made from or coated with a ceramic material. Other insulating materials may be used.

In one embodiment, the retainer 126 may be a leaf spring made of spring steel capable of operational temperatures ranging from ambient to about 800° C. In other embodiments, the retainer 126 may be made of other high-temperature materials such as Inconel. In further embodiments the retaining element 126 may be one or more clamps and/or screws arranged so as to urge the TCM 110 against the TEG module. The retainer 126 may include magnetic component configured to exert a force towards the hot surface of the TEG module.

In addition to exerting sufficient compressive force to urge the TCM against the TEG module, various other techniques for enhancing the thermal energy transfer from the TCM to the TEG may be used. For example, a thermally conductive, semi-compliant material (e.g., a graphite sheet) may be placed between the TCM and the hot surface 220 in order to decrease the thermal resistance between the two abutting surfaces. The semi-compliant material may conform to the surfaces when compressed minimizing or elimination air gaps between the two abutting surfaces. In another embodiment, a phase change material (for example, a compound of salt) may be provided at the interface between the TCM and the TEG module. The phase change material may change phase (e.g., the salt may melt) upon heating, decreasing the thermal resistance between the TCM and TEG module. The use of a phase change material may further improve uniformity of heating of the hot surface 220, for example because the fluidity of the phase-change material when melted may facilitate uniform distribution of thermal energy across the hot surface 220. A material with a highly conductive two dimensional structure, such as pyrolytic graphite, may be used as not only a compliant interface between the TCM and the TEG module, but also for the added benefit of increasing uniformity of surface temperature at the hot surface 220 of the TEG module. In such embodiments, the highly conductive planes of pyrolytic graphite may be oriented parallel to abutting surfaces of the TCM and TEG module (e.g., oriented parallel to the yz plane in FIG. 1).

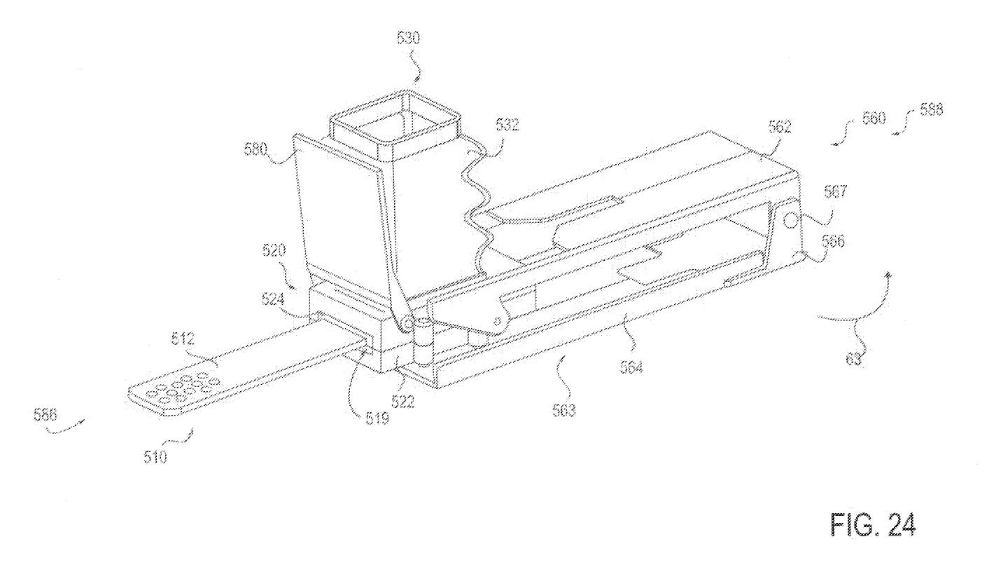

The housing 122 may include one or more openings 123, 125 configured to accommodate the portion of the TCM therethrough. For example, the housing 122 may include a first or top opening 123 which may be sized/shaped such that the short portion 116 of the TCM, the long portion 114 of the TCM, or both may be inserted therethrough. The housing 122 may include a second or bottom opening 125 which may be sized to receive the short portion 116 of the TCM, the long portion 114 of the TCM, or both. In some examples, either one of the first or second openings may be a different size than the other one of the openings, and each opening may be configured to accommodate only one of the portions of the TCM (e.g. the short or long portion) or a particular end of the TCM, in cases in which the TCM is not symmetric at both ends. In some examples, both of the openings (e.g., 123, 125) may be sufficiently large to receive either end of the TCM. While only two openings are described, it will be understood that any number of openings may be operatively provided in the housing 122 for accommodating a portion of the TCM. In some examples, an insulating material (524, see FIG. 24) may be provided along the perimeter or portions of the perimeter of one or more of the openings (e.g., 123, 125) such that heat transfer from the TCM to the housing 122 may be minimized in cases in which the TCM comes into direct physical contact with the opening. The opening (e.g., 123, 125) may be sized for a tight fit with the TCM end that is inserted therethrough and the tight fit may provide addition retention (e.g., in addition to retention force applied by the retainer) and/or stability of the TCM relative to the housing. The insulating material around the opening may be e.g., a high temperature capable plastic, which is compliant enough to facilitate a tight or interference fit while facilitating low or minimal heat loss to the housing.

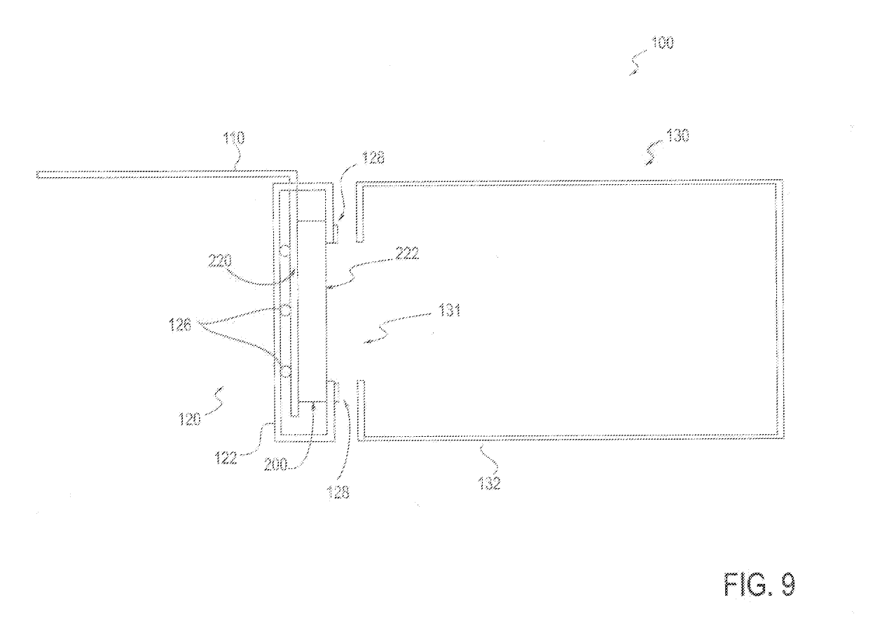

The housing 122 may be configured such that the cold surface 222 of the TEG module 200 is at least partially exposed. For example, the housing 122 may be implemented as an open-sided container and the TEG module 200 may be attached to the housing with the cold surface 222 facing the open side of the housing 122 (see e.g., FIG. 5). In other examples, the TEG module may be directly attached to the wall of the reservoir with the cold surface 222 abutting the reservoir. As previously discussed any number of techniques known in the art for reducing thermal resistance at the interface of the TEG module and reservoir may be used, for example, but without limitation, thermal grease, a compliant or semi-compliant thermally conductive material, and thermally conductive adhesive. In other examples, one or more apertures may be formed in the sidewall that abuts the reservoir (see e.g., FIG. 9). The aperture may be sufficiently large to expose most of or substantially the entire active portion of the cold surface of the TEG module. In further examples, the top ceramic plate 240 (e.g. the ceramic plate at the cold side) may be tailored to reduce thermal resistance with the heat transfer medium. For example, the exposed surface 240b of the top ceramic plate which may be provided in direct contact with the heat transfer medium, may be made thinner and/or more porous for improved thermal transfer across the plate to the heat sink.

The TEG device 120 and heat sink component 130 may be fixedly or non-removably attached for example by welding, bonding, fusing, of mechanically fastening the two together (e.g., using rivets, bolts, clips, clamps, and the like), as in the example in FIGS. 1-5. In other examples, the housing 122 and reservoir 132 may be over-molded to fixedly attach the two together. In further examples, the TEG device 120 and heat sink component 130 may be removably attached. In some instances, it may be advantageous to remove the heat sink component e.g., for storage and/or transport, as the heat sink component may increase the overall volume of the apparatus and reduce portability. Typically, the heat sink component 130 remains attached during use of the apparatus. Regardless of whether the TEG device 120 and heat sink component 130 are fixedly or removably attached, any of a variety of techniques as described herein may be used to reduce thermal resistance across the interface of the TEG device and the heat sink component.

The heat sink component 130 includes a reservoir 132 which is adapted to hold a heat transfer medium, also referred to herein as heat sink liquid. The heat sink reservoir may have a plurality of sides 134-138. The reservoir may have one or more open sides (e.g., top side 138 in the example in FIG. 1) which may be used to fill the reservoir with the heat transfer liquid. In other examples, an opening may be formed in any one of one of the sides for filling the reservoir with the liquid. The reservoir may include a lid or stopper for covering or plugging the opening or open side of the reservoir 132 during use. The reservoir 132 may be made from any material which is impermeable to the heat transfer medium and is sufficiently rigid to maintain a shape defining a given volume. The heat sink reservoir may be made from a metallic material (e.g., aluminum), elastomeric material (e.g., silicone or synthetic rubber), or plastic (e.g., high density polyurethane (HDPE), nylon, PC/ABS blend plastic, polyetheretherketone (PEEK), polyetherimide (Ultem), polyphenylene sulfide (Ryton or Fortron)), or a combination of these materials. In some examples, the reservoir 132 may be a generally rigid structure and any suitable material which can remain sufficiently rigid under the weight of the heat sink liquid may be used. In other examples, and as will be described with reference to the embodiment in FIGS. 18-29, the reservoir may be made from a flexible material and/or configured to collapse when not in use.

The reservoir 132 may include an interface opening 131 in the wall abutting the TEG device. As will be understood, the TEG device may be coupled to the reservoir 132 at one of the sides, for example the front side 136. In other examples, the TEG device may be coupled to the reservoir at the left or right sides 134, 134′, or at the bottom or side 137, as will be described with reference to FIGS. 18-29. The interface opening 131 may be a single aperture, e.g., as shown in FIG. 9, or a plurality of apertures or through holes 133, e.g., as shown in FIG. 5. The interface opening 131 extends through a thickness of the abutting wall of reservoir, such that during use, the heat transfer medium can pass through the interface opening and come in direct physical contact with the cold surface of the TEG module. In some examples, the interface opening 131 may be sized to correspond to an active area of the TEG module (e.g., 230 in FIG. 8A).

As described, the TEG device and heat sink component may be removably attached. The TEG device and heat sink components may be slidably attached, e.g., using a rail and groove type coupling. The heat sink component may be threadedly coupled to the TEG device. For example, a male or female thread may be provided to the reservoir 136 (e.g., along a perimeter of the opening 131 or along a perimeter of a protrusion extending from the surface 136). A cooperating thread may be provided at the housing 122 end such that the reservoir 136 may be threadedly secured to the TEG device by rotating of the reservoir 123 or TEG device about the longitudinal axis (e.g., x axis in FIG. 1). Any other suitable means for attachment (e.g., mechanical or magnetic means) may be used.

In examples in which the TEG device and heat sink component are removably attached, the housing 122 of the TEG device and/or the reservoir 132 may include an interface material at the interface joint 128 between the TEG device and heat sink component. For example, the interface material may be a compliant and/or insulating material to facilitate a leak proof coupling between the TEG device and heat sink component as well as to insulate against heat being absorbed by the reservoir at the joint 128. In some examples, the interface material may be rubber gasket, waterproof paste, or plumbers tape. In other examples, the interface material may be silicone, which may be provided along a perimeter of the interface opening 131, along a perimeter of each individual hole 133, or anywhere along the abutting surfaces of the housing 122 and reservoir 132 to minimize or prevent leakage of the liquid through the joint 128.

Referring now to FIGS. 1-3, and 11-16, the TCM 110 of the apparatus 100 may be removably attached in a “high”, “middle”, or “low” configuration, as depicted in FIGS. 15, 1, and 14, respectively. These alternate configurations of the apparatus may facilitate use of the apparatus with a variety of heat sources 80. For example, as shown in FIG. 16-(1), the apparatus 100 may be usable with a tall heat source 80′ in a “high” configuration in which the TCM extends above and away from the body of the apparatus. In the high configuration, the long portion 114 of the TCM is inserted in the top opening 123 of the housing 122 and provided in contact with the TEG module such that a portion of the long portion 114 extends upwards (e.g., in the vertical direction) from the housing 122 and the short portion 116 extends away (e.g., forwardly) from the housing 122. As shown in FIG. 16-(2), the apparatus 100 may be used with a medium-height heat source 80″ in a “middle” configuration, in which the short portion 116 of the TCM is inserted in the top opening 123 of the housing 122 and provided in contact with the TEG module as described herein. The apparatus 100 may be used in a “low” configuration with a heat source 80′″ which is low to the ground or disposed below ground level (see FIG. 16-(3)). In the low configuration, the TCM may be inserted in the bottom slot 125. Either the long portion or short portion of the TCM may be inserted in the bottom slot, for example depending on the height of the heat source and/or desired reach.

As described, the apparatus may be configured to have a particular reach to enable the body of the apparatus to be substantially isolated from the heat source making it easier to control the temperature of certain components which may be heat sensitive. As may be appreciated, the apparatus may also have a small frontal cross-sectional area, e.g., to reduce or minimize heating the TEG device. In this regard, the front or forward-facing surface of housing 122, which in some uses faces the fire or other heat source, can be relatively small. Furthermore, the housing can serve as a heat shield for the heat sink component 130. In some examples, an additional heat shield may be provided, as described with reference to the embodiment in FIGS. 18-29.

The portable apparatus 100 may be a hand-held apparatus. As such, the apparatus may have a compact size and/or may include a handle 150 for holding the device proximate to the heat source. The handle 150 may be integrally formed with the reservoir 112 or the handle 150 may be fixedly or removably attached to the heat sink component 110 using conventional fastening techniques. The handle 150 may be disposed at a location away from (e.g. opposite) the TEG 120. The handle 150 may be made, at least in part, from a thermally insulating material and/or be configured to minimize transfer of heat from the heat sink towards or along the handle so as to enable the user to safely move/handle the apparatus when hot. In further examples, instead of or in addition to a handle, the portable apparatus may include a support structure for maintaining the apparatus in a desired position relative to the heat source, as will be described e.g., with reference to FIGS. 18-29.

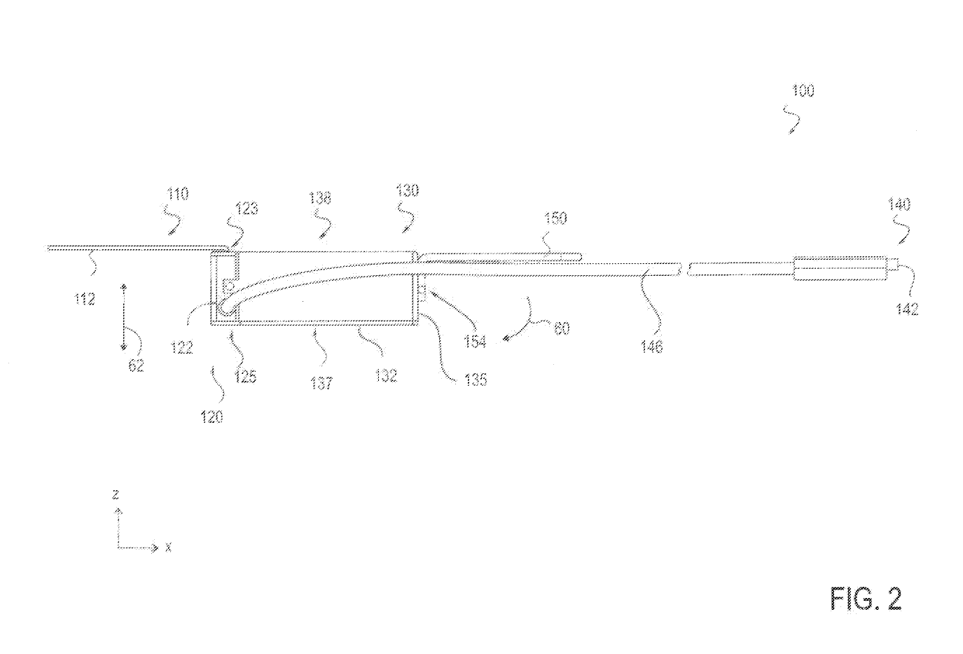

The handle 150 may be collapsible for storage thereby facilitating a compact configuration e.g., as shown in FIGS. 11-13. The handle 150 may be pivotally attached to the heat sink component at pivotal joint 154 such that rotation about the pivotal joint (e.g., as indicated by arrow 60 in FIG. 2) causes the handle to collapse or fold downward and towards the reservoir. In this manner, the handle 180 may be collapsed or folded under the reservoir 130 and nested with the reservoir while the apparatus is not in use. During use, the handle may be expanded by applying a force outwardly (e.g., pivotally in a direction opposite the direction indicated by arrow 60) so that the handle 150 may be pivoted about the pivotal joint 154. Other implementations may be used. For example, the handle may be a single elongate member, which is slidably attached (for example using a rail or a friction joint) to one or more of the sidewalls of the reservoir. In such embodiment, the handle may be collapsible by sliding the handle forward along a generally parallel path relative to the sidewall of the reservoir. Spring loaded or other conventional retention mechanisms (e.g., friction) may be used to maintain the handle in its collapsed and/or expanded configuration and resist collapsing of the handle during use. The TCM 110 may also be nested or collapsed in the compact configuration depicted in FIGS. 11-13. As described, the TCM 110 may be removably attached to the TEG device 120. As such, the TCM 110 may be removable when not in use. The TCM 110 may be stored separately or it may be rotated about the vertical axis and inserted into the top opening 123 facilitating the compact configuration of apparatus 100, as shown in FIGS. 11-13.

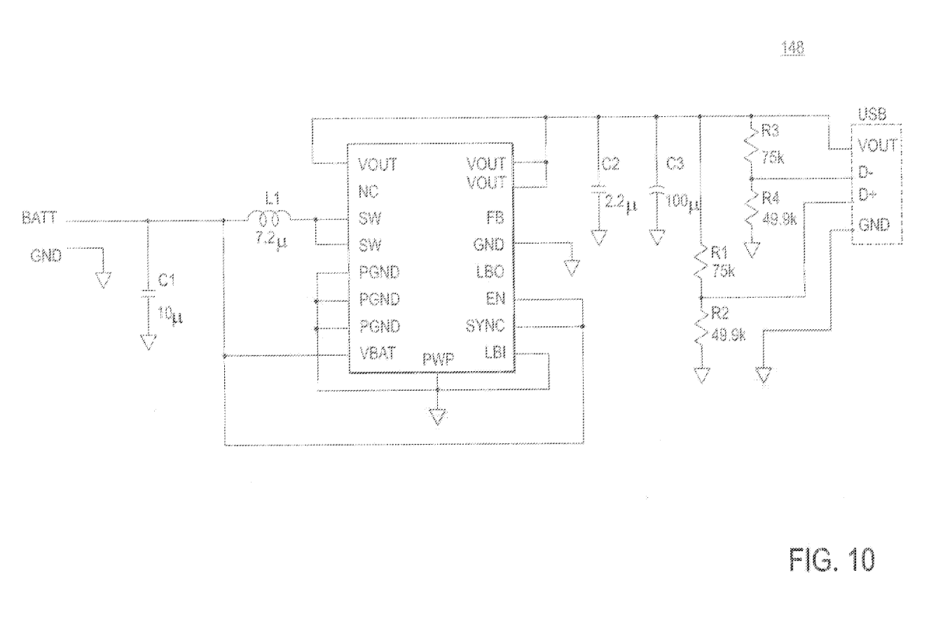

The apparatus 100 may also include a power component 140 for providing electrical energy generated by the TEG module to an electronic device. The power component 140 may include an electrical connector 142, circuitry 148 (see e.g., FIGS. 3, and 10), and an enclosure 144 enclosing the circuitry and at least partially enclosing the connector 142. In this regard, the electrical connector 140 may be operatively coupled to the TEG module 200 for delivering electrical energy generated by the TEG module to an electrical device (not shown). The electrical connector 142 may be, without being limited to, a USB connector or any of a variety of standard connectors for charging electrical devices such as laptops, tablets, e-readers, mobile phones, smart phones, portable multi-media devices, rechargeable batteries, and other portable electronics. In some embodiments, the power component 140 may include an internal storage device (e.g., internal battery) at least partially within the enclosure 144. Electrical energy generated by the TEG may be stored in the internal storage device (e.g., internal battery) prior to charging an external electrical device (e.g., cell phone, light, battery, GPS, media/music player, etc.). As such, stored electrical energy may be available for charging even after the apparatus 100 is removed from the heat source.

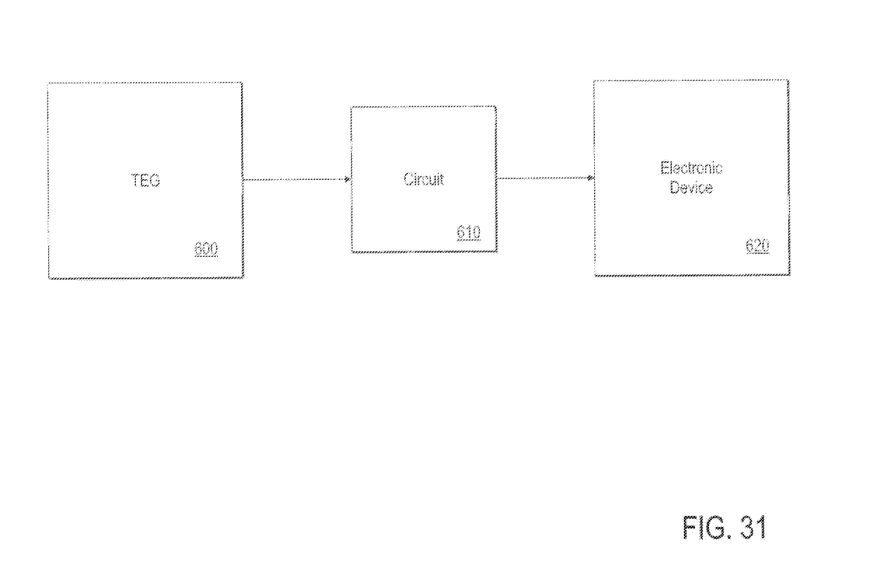

In some examples, some or all of the components of power component 140 may be integral with the TEG device (e.g., as shown in FIGS. 18-29). In other examples, the power component 140 may be separate from and/or some distance away from the TEG device, for example, to avoid placement of the electrical device while charging close to the source of thermal energy and thereby keeping the electrical device cool during charging. In such examples, the power component 140 may be attached to the TEG device 120 via a cable 146 which extends from the TEG device 120. Any length of cable may be used. The cable 146 may be non-removably attached to the housing 122 (e.g., via an electrical feedthrough). In other examples, the power component 140 may be separable from the body of the apparatus (e.g., as will be further described with reference to FIG. 31). In a specific example, the cable 146 may include two separately electrically-insulated wires (e.g., positive and negative leads from the TEG module) and the two wires may be housed in an external insulator that protects the wires from heat, flame, and mechanical wear. In another embodiment (not shown) the cable 146 may exit the heat sink reservoir 132 or another component of the apparatus in a direction away from the cold surface 222 of the TEG module, wherein such positioning may reduce exposure of the cable 146 to the elevated temperatures of the heat source.

The circuitry 148 may be configured to convert variable electrical input, as may be generated by the TEG module, into a voltage and/or current profile tailored for a particular electronic device or operable for charging a plurality of different electronic devices, as may be desired. Any suitable circuitry may be used, for example as depicted in FIG. 10. In the example in FIG. 10, a boost converter may be used to create 5 volts, which may be deemed the USB standard, and communicate an appropriate current through data pins such that the current may be supplied to the electronic device through the USB connector. For example, 2.0 V communicates that the charging device can supply 500 mA of current. The circuit may employ a small energy storage system such that this amount of current may be provided to the mobile phone, creating a “handshake” in which charging compatibility is confirmed. This may enable the apparatus 100 to continue charging the electrical device in sub-optimal conditions (e.g., when power is lower than optimal). In some examples, the circuitry 148 may be tailored to a particular TEG module and operating conditions of the particular TEG module in order to achieve maximum efficiency from the TEG module. Tailoring of the circuitry 148 may be achieved by matching the impedance of the circuitry 148 with the peak power resistive load on the TEG module, at the operating conditions. In still other embodiments, the resistance of the circuitry 148 may be adjustable depending on the temperature of the hot surface of the TEG module. Adjustable resistance circuitry may be implemented by mounting an electronic component inside of the thermal mass (e.g., ceramic plate) on the hot side of the TEG module such that a decrease in the temperature at the hot side may cause change in the impedance of the circuitry thereby maintaining the apparatus at maximum power output. Materials with resistive properties for given temperatures are known and may be used in conjunction with the circuitry 148 to create a passive feedback loop.

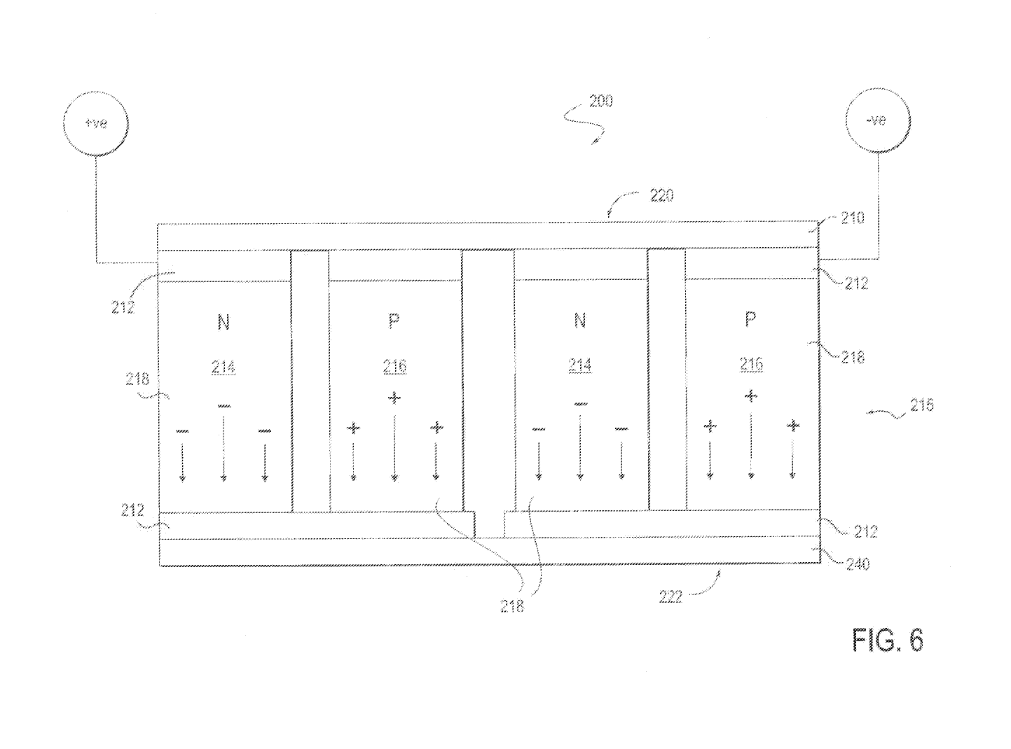

FIG. 6 depicts a simplified illustration of a TEG module 200 according to the present disclosure to facilitate an understanding of the functionality of the TEG module 200. As described, the TEG module 200 includes a first or hot surface 220 and a second or cold surface 222. Thermally conductive ceramic 210, 240 may be disposed in contact with each of the hot and cold surfaces (220, 222, respectively) on each side of a semiconductor material 215, which is selectively coupled to metal interconnects 212 disposed between the ceramic 210 and semiconductor 215 layers, as depicted in FIG. 6. The TEG module 200 is powered by a difference in temperature between the two surfaces (e.g., the hot surface 123 and the cold surface 125). This temperature difference may cause diffusion of mobile (charge-carrying) particles from the higher temperature region (e.g., hot surface) to the lower temperature region (e.g. cold surface), e.g., as shown in FIG. 6. This process may be thought of as being analogous to high pressure zones caused by warm pockets of air creating local wind (diffusion) towards lower temperature (lower pressure) zones.

A semiconductor material 215 may be used to form the temperature biased TEG module 200 so as to cause diffusion of charged particle (positive or negative) in a particular direction. The TEG module 200 may include a plurality of P doped regions 216 and N doped regions 214. Each P doped (e.g., “p-type”) semiconductor region 216 has positively charged particles (e.g. holes) as mobile charge carriers, which diffuse towards the lower temperature region (e.g., cold surface). Each N doped (e.g., “n-type”) semiconductor regions 214 has negatively charged particles (e.g., electrons) as the mobile charge carriers, which also diffuse towards the lower temperature region (e.g., cold surface). The p-type and n-type semiconductor regions (e.g., 214, 216 or collectively referred to as semiconductor regions or legs 218) are selectively connected in series such that potential difference (voltage) generated across each of the p-type and n-type semiconductor regions is cumulative thereby generating an appreciable amount of electrical power. It will be understood that for illustration and simplicity, only four individual p-type and/or n-type semiconductor regions (also referred to herein as semiconductor legs or structures) are shown in FIG. 6. In practice, a TEG module according to the present disclosure may include a larger number of semiconductor legs 218, for example hundreds of semiconductor legs 218 selectively coupled in series using metal interconnects to produce a current under the application of a temperature differential.

The thermoelectric generation process according to the present disclosure may be governed by the equations that follow.

$$Eq . 1 ) Z \overline{T} = \frac{{( {S}_{p} + {S}_{n} )}^{2}}{[ {( {ρ}_{n} {k}_{n} )}^{1 / 2} + {( {ρ}_{p} {k}_{p} )}^{1 / 2} ]} \overline{T} \approx \frac{σ {S}^{2}}{k} \overline{T} , \\ Eq . 2 \text{)} \overline{T} = \frac{{( {T}_{2} + {T}_{1} )}^{2}}{2} , \\ Eq . 3 \text{)} {η}_{max} = [ \frac{{T}_{H} - {T}_{C}}{{T}_{H}} ] [ \frac{\sqrt{1 + Z \overline{T}} - 1}{\sqrt{1 + Z \overline{T}} + \frac{{T}_{C}}{{T}_{H}}} ] ,$$

wherein, Z T̅=Figure of Merit, S=Seebeck Coefficient, σ=Electrical Conductivity, k=Thermal Conductivity, T=Temperature, and η=Efficiency.

From the above equations, Eq. 1 may define the “Figure of Merit” which may be loosely providing a measure of the TEG module performance. In equation 1, T_bar is an average temperature which is defined by Eq. 2, and Eq. 3 defines an efficiency of the TEG as a function of hot and cold temperatures (T_{H} and T_{C} at the hot and cold surfaces, respectively) and the Figure of Merit.

Commercially available thermoelectric generators may be used. For example, a suitable thermoelectric generator may be a Model No. TG12-4-01LS or Model No. TG12-4 provided by Marlow Industries, Dallas, Tex. Commercially available thermoelectric generators may be configured to operate in a range of temperatures. For example, the TEG module available from Marlow Industries may operate at temperatures ranging from ambient temperature to 800° C. at the hot side and temperatures ranging from −50° C. to 300° C. at the cold side. In some embodiments, the hot side temperature ranges from ambient temperature to 300° C. and the cold side temperature ranges from ambient to 180° C.

Referring now to FIGS. 7 and 8, two embodiments of TEG modules according to the present disclosure will be further described. The TEG module 200 includes first and second ceramic plates 210, 240 and a plurality of semiconductor regions or legs 218 disposed therebetween. Each of the ceramic plates 210, 240 has a bottom and top surfaces 210a, 210b and 240a, 240b, respectively and the semiconductor regions or legs 218 are sandwiched between the top surface 210b of plate 210 and the bottom surface 240a of plate 240. The metal interconnects are omitted for simplicity of illustration from the FIGS. 7 and 8. The exposed or bottom surface 210a of the first or bottom ceramic plate 210 corresponds to the cold surface 220 of the TEG module and the exposed or top surface 240b of the second or top ceramic plate 240 corresponds to the hot surface 222 of the TEG module. The top and bottom plates 210 and 240 may be the same or substantially the same size, or they may differ in size as shown in the examples in FIGS. 7 and 8. For example, the top or hot plate 240 may be smaller in plan view as compared to the bottom or cold plate 210 and the bottom plate 210 may include an underhang to which certain other components may be attached (e.g., solder pads 224). Wiring may be connected at the solder pads and coupled to circuitry (internal or external to the TEG device) for receiving the charge generated by the TEG module and providing electrical energy to an electronic device. The semiconductor structures 218 may be arrange in any pattern (e.g., an array) and may extend substantially to the perimeter 226 of the top plate 240 (FIGS. 7A-7C). The TEG module 200 may include air or other insulating medium in the gaps or spaces between the individual semiconductor legs 218. In other examples, and as shown in FIGS. 8A-8C, the semiconductor legs 218 may span only a first portion 230 of the area defined by perimeter 226 and a perimeter portion 228 may be substantially free of semiconductor legs 218. The perimeter space 232 around the semiconductor structures may function as insulator and/or additional insulating medium (e.g., fiberglass or high temperature plastic material) may be provided in the perimeter space 232 to improve the heat flow path through the TEG module and minimize heat loss to the area surrounding the TEG module.

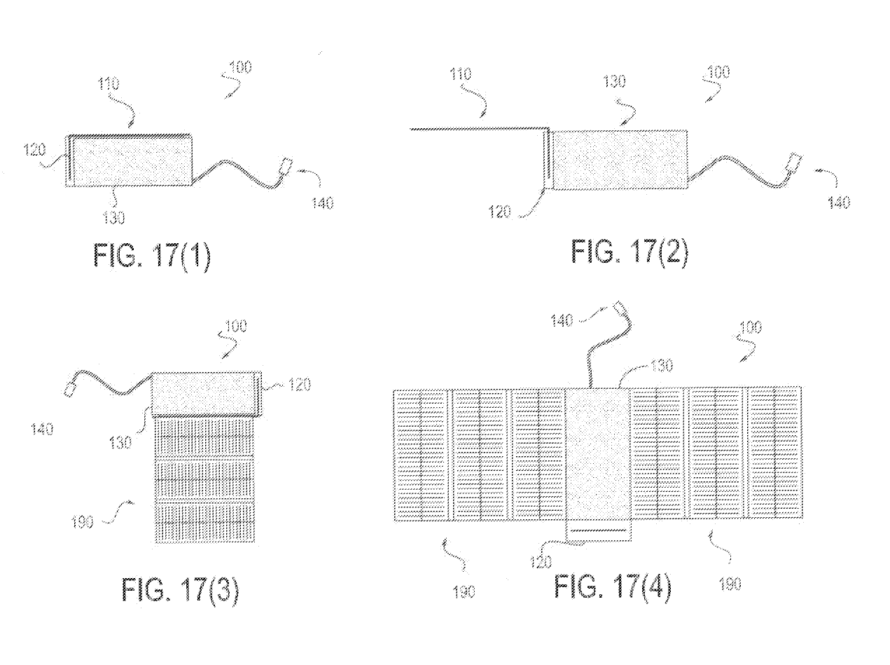

In another embodiment, the apparatus 100 further includes one or more photovoltaic (PV) modules or cells 190 which may be removably or fixedly attached at the heat sink component 130 (e.g., as shown in FIG. 17) or other structure of the apparatus 100 (e.g. the support structure or housing). The cable 146 may be coupled to both the TEG module and the one or more photovoltaic cells. In the embodiment in FIG. 17, the apparatus 100 may be used to generate electricity with the TEG module through the thermoelectric process and/or using the PV module 190. Both of the electricity generating mechanisms may be used simultaneously or independently from one another and an advantage may be obtained from the sharing of the circuitry in the electrical connector 140. For example, the TEG module may be used independently from the PV module, e.g., as shown in FIG. 17-(2) in which the TCM is extended for use. In other examples, the PV module may be used independently, e.g., as shown in FIG. 17-(4) in which the TCM is provided in the nested position. As will be appreciated, some of the advantages of such an embodiment may include integration of a PV module with a thermoelectric generator, thermal management which may be shared between the two electricity generating modules, as well as shared power electronics. Certain ones of the components of the apparatus may be detachable. For example, the PV panels may be removably attached to one or more walls of the reservoir. In other examples, or in addition to being removable, the PV panels may be collapsible for storage.

FIGS. 18-29 depict a second embodiment of an apparatus for converting thermal energy to electrical energy. The apparatus 500 may include a thermally-conductive element 510, also referred to herein as thermally-conductive member (TCM) 510, a thermoelectric generator (TEG) device 520, and a heat sink 530. Similar to the apparatus 100, the TEG device 520 of the apparatus 500 includes a support structure 561 that includes a housing 522 and a leg assembly. The TEG device 520 further includes a TEG module 200 enclosed, at least partially, within the housing 522. The heat sink 530 of the apparatus 500 includes a reservoir 532, which may be configured to include some or all of the features of the reservoir 132 of apparatus 100.

In the embodiment in FIGS. 18-29, the TCM 510 is a planar element 512, which may be made from the same materials as the TCM 110 and may include some or all of the features of the TCM 110. The TCM 510 may include a first or exposed portion 514. The exposed portion 514 may extend outward or forwardly from the body of the apparatus 500 for placement of the exposed portion 514 in contact with the open flame. The TCM 510 includes a second or enclosed portion 516. The second portion 516 may be substantially enclosed within the housing 522 of the TEG device during use of the apparatus. The TCM 510 may be a unitary member (e.g., a monolith) made from the same continuous material, for example a block or a sheet of metal.

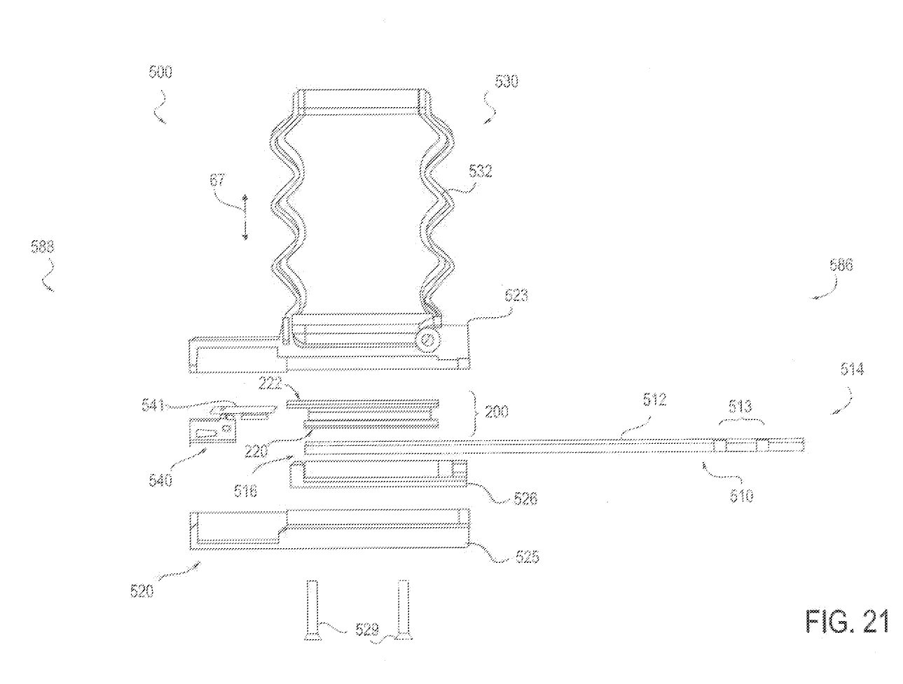

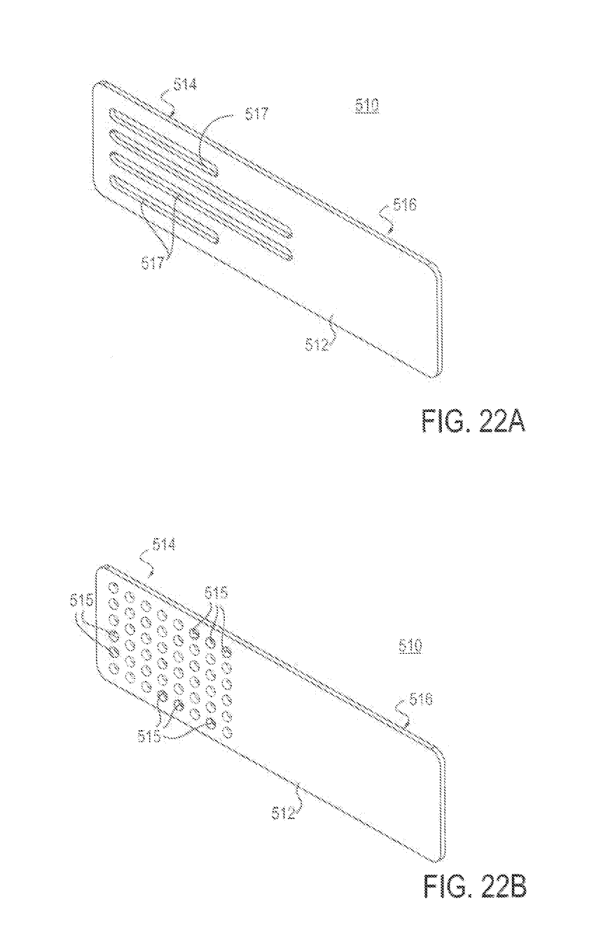

The TCM (e.g., 110 and/or 510) may include features, also referred to herein as heat vias 513, to reduce obstruction of the heat source by the TCM (see FIGS. 22A-22B). The heat vias 513 may be one or more ridges, holes 515, slits 517, or other openings formed through a thickness of the TCM. The heat vias 513 may have any shape (e.g., circular, rectangular, oval, elongate) as may be desired to achieve a generally uninhibited use of the fire. The size, shape and/or arrangement of the heat vias 513 along the exposed portion 514 of the TCM may be selected such that the heat/flames can flow around the TCM 510 in a controlled manner which optimizes the heat transfer to the TCM 510, without impeding the primary use of the heat source (for example, cooking) The heat vias 513 may be sufficiently large such that they permit transfer of heat upwards or through the TCM 510, for example towards a cooking pot, without being too large to cause the surface area of the TCM to become significantly “transparent” to the heat source and adversely affect or prevent lateral thermal conductivity of the TCM 510. The heat vias 513 may be arranged in an artistic/decorative pattern or may be arranged in a pattern which conveys information. For example, the heat vias 513 may be arranged in a pattern, which may be customized by the manufacturer or user to convey information about the TCM or the user and/or instructions for proper use of the TCM. The TCM may include additional features, for example protrusions and/or detents or slots, which may indicate additional instructive information (e.g., an appropriate distance for placement of the TCM relative to the heat source).

The TEG device 520 may include some or all of the components as described with respect to the apparatus 100. For example, the TEG device may include a housing 522 and a TEG module 200. As with the apparatus 100, while only one TEG module 200 is depicted, it will be understood that the TEG device 520 may include any number of individual TEG modules 200 arranged within the housing 522. The TEG module(s) 200 may be configured according to any of the examples described herein. As previously described, the TEG module 200 may include a first or hot surface 220 and a second or cold surface 222 opposite the hot surface.

The housing 522 of the TEG device 520 may enclose at least a portion of the TCM 510 (e.g., the second portion 516), which portion may be provided in direct physical contact with the TEG module 200 as described herein. The housing 522 may be a unitary component or it may be assembled from a plurality of components. For example, and as shown in FIGS. 18-21, the housing 522 may include a first or top housing component 523 and a second or bottom housing component 525, which are configured for a cooperating fit at the interface or seam 257. The lower housing component 525 and/or upper housing component 523 may be made from a metallic material (e.g., aluminum), elastomeric material (e.g., silicone or synthetic rubber), or plastic (e.g., high density polyurethane (HDPE), nylon, PC/ABS blend plastic, polyetheretherketone (PEEK), polyetherimide (Ultem), polyphenylene sulfide (Ryton or Fortron)).

As previously described the TCM 510 may be removably or non-removably attached to the TEG device. In the example in FIGS. 18-29, the TCM is fixedly or non-removably attached, which in the context of this disclosure implies that the TCM is not intended to be removed during normal use of the apparatus (e.g., by the user or consumer). The TCM 510 in this embodiment is mounted to the bottom of the reservoir 532. The reservoir 532 may include a bottom surface with an aperture for allowing direct contact of the heat sink fluid with the TEG module.

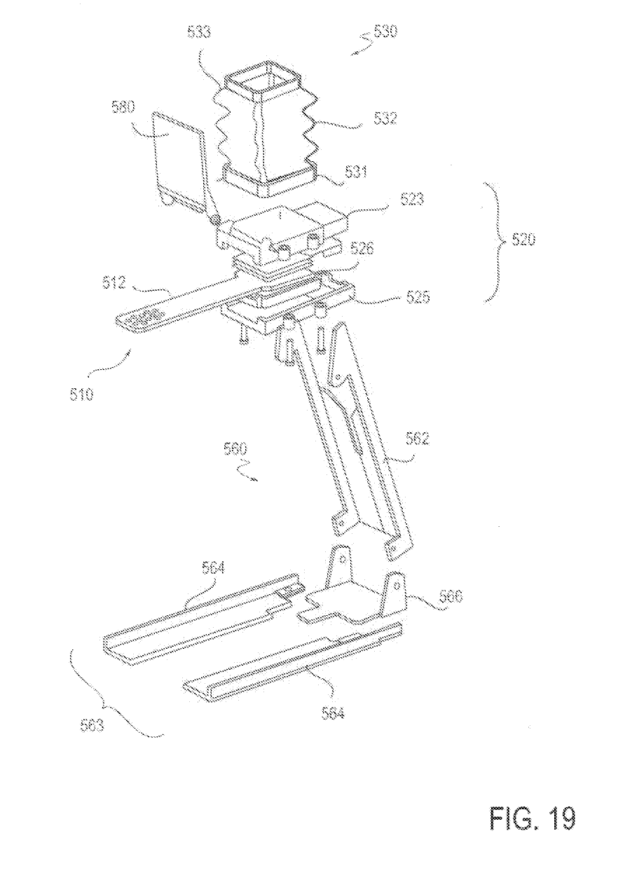

In other examples, the reservoir 532 may include a first or contact plate 531 (see FIG. 19), which may be made from a different material than other portions of the reservoir (e.g., the one or more sidewalls). The contact plate 531 in the depicted example is located at the bottom of the reservoir and may be referred to as bottom plate; however in other examples, and depending on the particular configuration the contact plate may be located at any other side of the reservoir. The contact plate 531 (e.g., bottom plate 531) may be made from a thermally conductive material (e.g., a metal, or conductive composite material) while the sidewalls 533 of the reservoir may be made from an insulating material (e.g., plastic, such as silicone or any high temperature capable plastic). The contact plate 531 may be made from materials such as aluminum, steel, anodized aluminum, copper, titanium, or an alloy of these materials, which may enhance the mechanical and/or thermal performance across the TEG-to-heat sink interface. The contact or contact plate 531 may have features (e.g., fins or pins) extending upward or inward into the reservoir for increased surface area, and correspondingly increased thermal energy transfer from the heat sink reservoir to the heat sink liquid. The reservoir 532 may also contain features such as nucleation sites for boiling bubbles, which may further enhance the transfer of heat away from the contact plate 531. In other examples, the contact plate 531 may be incorporated into the upper or top housing 523, such that they are the same piece. In this embodiment, the sidewalls 533 of the reservoir 532 are attached directly to the top housing 523.

In some examples, the reservoir may be formed at least in part by a flexible plastic material that is movable between a first or contracted configuration for storage and a second or expanded configuration for operation. The sidewalls 533 of the reservoir 532 may be made from a material which is flexible enough to be collapsed when the apparatus 500 is not in use, but durable enough to withstand mechanical cycling, as well as thermal cycling. In one embodiment, the sidewalls 533 are made of a high-temperature silicone material which may be molded to the contact plate 531. The plastic material of the reservoir may be formed in an accordion configuration, and for example have a plurality of pleated sections. In other examples, the sidewalls 533 of the reservoir 532 and the contact plate 531 are made from the same or same type of material (e.g., a metallic material). In some embodiments, the apparatus 500 may include a heat shield 580, which may be pivotally coupled to the heat sink component. In other embodiments, the heat shield 580 may be pivotally coupled to the housing 522 of the TEG device using any conventional pivotal joint 582 (e.g., a pin, a hinge, or others). During use, the heat shield 580 may be deployed by rotating the heat shield 580 (e.g., as indicated by arrow 66) to provide the heat shield 580 from a first or stowed position to a second or deployed position. When the apparatus is not in use, the heat shield 580 may be folded down such that the heat shield 580 rests adjacent or in contact with the top of the housing 522. As described, the heat sink component 530 may be removably attached to the TEG device to enable the heat sink component 530 to be disassembled from the apparatus 500 prior to storage or transport. In other examples, in which the heat sink component 530 is attached in non-removable manner, the reservoir 532 of the heat sink component may be me collapsed under the pivotable heat shield. The heat shield may be made from any suitable material, e.g., any material which can withstand high temperatures as may be expected at the front of the apparatus during use. The heat shield 580 in some embodiments may be made from anodized aluminum or another metal, or other high-temperature materials.

Similar to the apparatus 100, the TEG device 520 of the apparatus 500 may include a retention element or retainer 526. The retention element may be configured to contact the TCM when inserted into the housing 522 and press the TCM against the TEG module while insulating or inhibiting transfer of heat to the housing 522 through the retention element. In some examples, the retention element 526 may be a compression member (e.g. a block of compliant material, such as silicone). The compression member may be a solid block of material such that substantially the entire top surface of the compression member in physical contact with the TCM or it may have one or more cavities or through holes (e.g., for improved compliance and/or economy of material) such that only a portion of the top surface (e.g., a perimeter of the top surface) contact the TCM. The retention element may be attached to the bottom housing component 525 by any conventional means (e.g., adhesive, mechanical fasteners 529, and the like). In some examples, the retention element need not be attached to the housing and may simply remain in place under compressive forces when the top and bottom housing components are assembled together.

In the embodiment in FIGS. 18-29, the apparatus 500 includes a support structure or leg assembly 560, which may include a stand or leg assembly 562 and a base assembly 563. The stand 562 may include a longitudinal member having a fixed length. In some examples, the stand may be removably attached to the thermoelectric generator. The stand 562 may be pivotally attached to the base assembly at a first or bottom pivotal joint 567 and may also be pivotally attached to the housing 522 of the TEG device at a second or top pivotal joint 569. A height of the stand 562 may be varied by varying an angle between the longitudinal member and the base assembly 563 (e.g., by rotating the stand 562 about the bottom pivotal joint 567 as indicated by the arrow 64. In other examples, the stand 562 may be implemented as a telescoping member with an adjustable length, which may be varied by outwardly sliding overlapping sections (e.g., cylindrical sections) of the stand. Other implementations may also be used without departing from the scope of the present disclosure. The top pivotal joint may include insulating materials, e.g., in embodiments in which the housing 522 is made from a thermally conductive material to reduce any heat loss to the leg assembly 560.

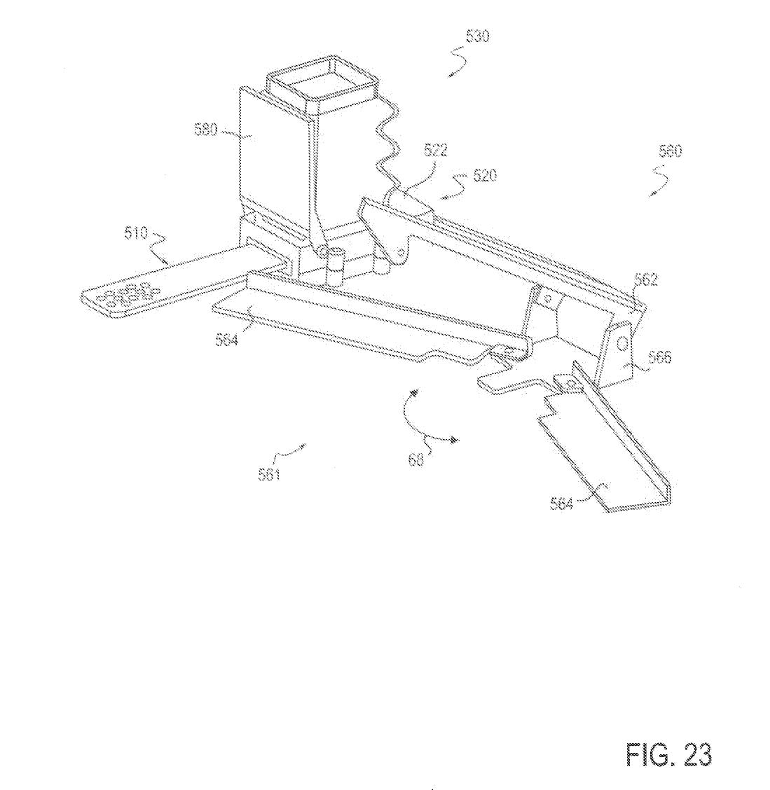

The base assembly 563 may be configured to provide stability when the apparatus 500 is in use. The base assembly 563 may include one or more feet or pads 564 each of which may be independently adjustable or movable. The base assembly 563 in the embodiment in FIGS. 18-21 includes two elongate wing flanges 564 each pivotally attached to a base bracket 566. Each of the wing flanges 564 are pivotable outward from a centerline of the base bracket (e.g., as indicated by arrow 68 in FIG. 23) to provide a wide foot print if desired. Each wing flange may be pivotable from its initial or collapsed position up to 90 degrees, thereby enabling the foot pads to be swept outward to define an angle of up to 180 degrees therebetween. The angle between the wing flanges may be adjusted prior to use, e.g., to provide stability and/or provide the apparatus 500 in a particular position relative to the heat source (e.g., the wing flanges may be spread wider apart to bring the apparatus 500 closer to the heat source). One or more of the pivotal joints of the leg assembly may include a friction joint to resist the rotation about the pivotal joint and maintain the components in their collapsed or expanded position. Other retention mechanisms, such as latches or pin-type locking mechanisms may be used to maintain the leg assembly in either a collapsed or expanded positions. It will be understood that the particular example of a leg assembly depicted herein is illustrative only and other implementations may be used. For example, the leg assembly may be a tripod or multi-pod structure, which includes one or more legs for supporting the TEG device and reservoir over a source of heat energy.

As described herein, an apparatus according to the present disclosure may include power conversion circuitry for delivering power to an external electrical device (not shown) and an electrical connector for coupling to the external electrical device. For example, apparatus 500 can include a power component of any suitable type for example power component 140. The electrical connector may be a standardized connector, such as a USB connector. In other examples, the circuitry may be integrated within the housing 522 of the TEG device, as in the embodiment in FIGS. 18-21. The circuitry 541 and connector 540 are attached to the TEG module and enclosed, at least partially, within the housing 522 such that the circuitry may be protected from high temperatures that may be encountered during use by the housing 522 of the TEG device. The connector 540 may be a female USB connector to which the electronic device may be coupled. In yet further examples, the power conversion circuitry may be separate (e.g., enclosed in a separate enclosure) from the body of the apparatus 500. The power conversion circuitry may be connected to the TEG module via a non-removable cable, for example as described with reference to the first embodiment, or the power conversion circuitry 610 may be separable from or modular with the energy generating apparatus 600 as shown in FIG. 31. The apparatus may be equipped with an indicator (e.g., LED(s)) operatively coupled to the circuitry to indicate the efficiency, voltage, current or power output of the TEG module, or level of progress of the charge cycle of the internal storage device and/or the external electronic device.

FIGS. 18, 23, and 24 depict alternate configurations of the apparatus 500 (e.g., for use with different heat sources. As described, the apparatus may be provided with a support structure or leg assembly which is operable to adjust a height of the apparatus 500 above some support surface (e.g., the surface upon which the apparatus is placed). FIG. 18 depicts a first or “high” configuration in which the apparatus is adjusted for use with taller heat sources. FIGS. 23 and 24 depict a second or “medium” configuration and a third or “low” configuration for use with heat sources which are closer to the support surface or below the support surface. The apparatus 500 may be provided in yet another alternate expanded configuration in which leg assembly 560 may serve as a handle. The apparatus 500 may be provided into the expanded configuration by rotating the base assembly 563 about the bottom pivotal joint 567 (e.g., as indicated by arrow 63 in FIG. 24, 25). In the expanded configuration, the base assembly (e.g., wing flanges 564) may be substantially parallel with the stand 562. The wing flanges 564 may remain in their neutral of folded position (e.g., the angle between the wing flanges remains at about zero)

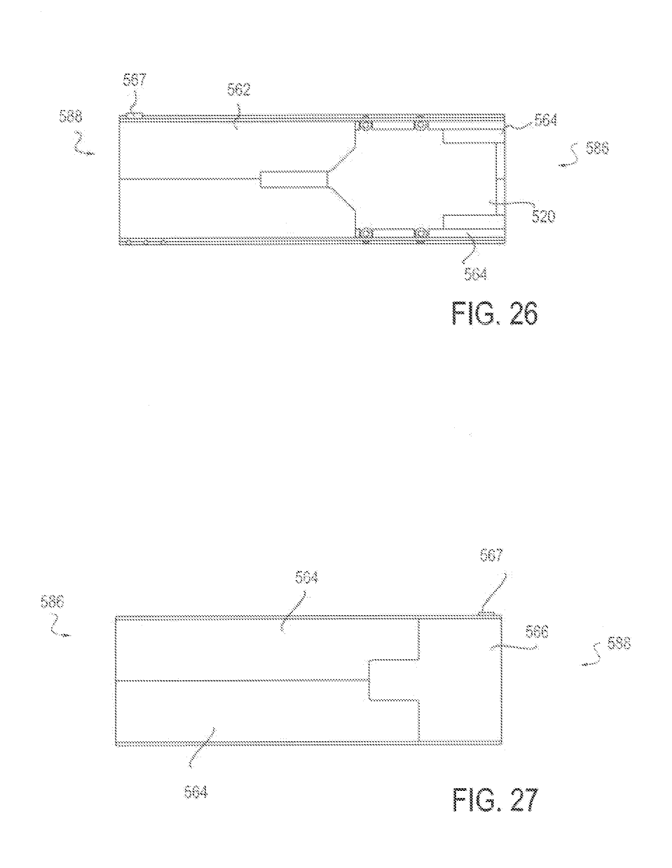

As described, the apparatus 500 may be configured for portability, e.g., by providing the apparatus 500 in a compact or folded or low-profile configuration, as shown in FIGS. 26-30. The apparatus 500 may be collapsed when not in use, e.g., for transport and/or storage. FIGS. 26-30 show a top, bottom, front, side, and back views of the apparatus 500 in the compact or folded configuration. The front side 586 of the apparatus is the side which faces the heat source during use and the back side 588 is the side which faces away from the heat source during use. FIG. 27 The apparatus 500 may be foldable down to a compact, generally cuboid shape. In order to collapse the apparatus to the compact configuration, the user may remove or collapse the heat sink 530 and fold the heat shield 580 such that it rests flat against the TEG device 520 or against the TCM device 512. The housing 522 of the TEG device with the TCM 510 attached thereto may be folded inward towards the stand 562 (e.g., by rotating the TEG device in the direction indicated by arrow 586). In this manner, when folded, the TCM becomes surrounded by the support structure within a cavity 589 defined by the folded support structure and may thus be protected from damage. The winged flanges are folded to their neutral position and then folded towards the stand 562. The resulting compact or low-profile configuration may be sufficiently small and portable to be carried e.g., in a pocket or a backpack.

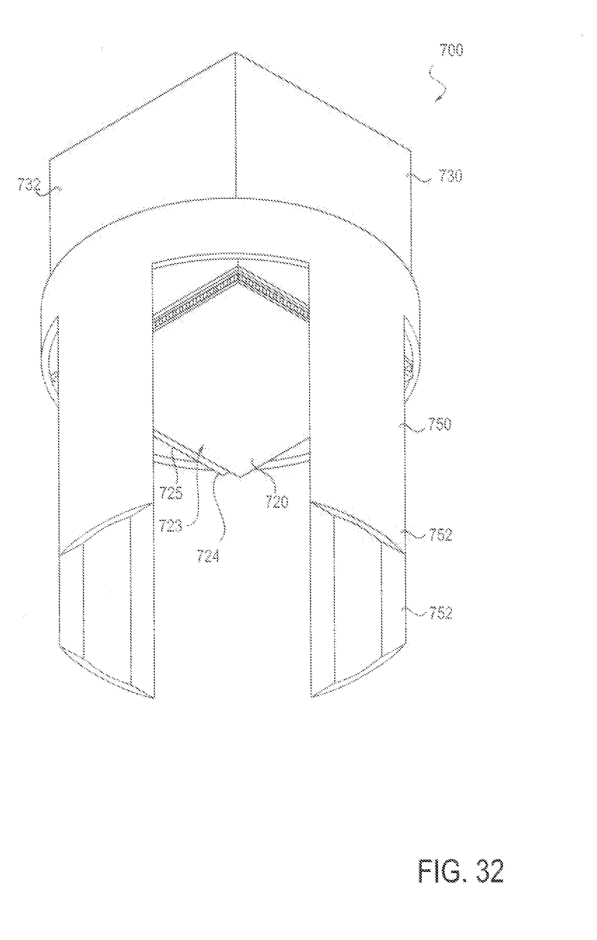

FIG. 32 depicts yet another embodiment of an apparatus 700 according to the present disclosure. The apparatus 700 includes a TEG module 720, a heat sink component 730 and a support structure or stand 750. The heat sink component 730 may include a reservoir 732 and may be implemented according to any of the examples herein. The TEG module 720 may be implemented according to any of the examples herein. For examples, TEG module 720 may the TEG module 200 as described with reference to FIG. 1-8. The TEG module 720 may include a hot surface 723 which faces downward or away from the heat sink component. The TEG module 720 further includes a cold surface 725 which may be mounted (e.g., adhered or welded) to a bottom wall of the reservoir 732. In other examples, as in the apparatuses described in FIGS. 1-5, 11-15 and 18-30, the reservoir may not include a contact plate and the bottom of the reservoir may instead be open to the TEG device such that the heat sink liquid is in direct contact with the cold surface of the TEG module. In yet further examples, as with in the apparatuses described in FIGS. 1-5, 11-15 and 18-30, the contact plate may include one or more apertures for providing the heat sink liquid in direct contact with the cold surface of the TEG module.

The apparatus may further include a power component, for example a power component similar to power component 140, which may include a connector, for example a connector similar to connector 142, for coupling to an electrical device (not shown) such that electricity generated by the TEG module 720 may be delivered to the electrical device. Circuitry (not shown), for example circuitry similar to circuitry 148, may be coupled to the solder pads 724 of the TEG module and configured to provide electrical energy to the electrical device.

The support structure 750 may include a plurality of legs 752 which are configured to maintain the TEG module and heat sink component in a particular position relative to the heat source. As will be appreciated, the apparatus 700 may be used with a dedicated heat source. The heat source may be, without being limited to, a candle, an alcohol burner, a hexamine-fuel-based heat source, an oil candle, or a jellied alcohol burner. The support structure 750 may be sized and/or shaped such that the apparatus 700 may be placed directly above the heat source with flame coming into direct contact with the exposed hot surface 723. The support structure 750 may be removable in some examples. In some examples, the legs 752 may be collapsible, for example, by telescoping, folding, rotating, or sliding upward along the length of the reservoir. The length of each leg 752 may be adjustable using an adjustment mechanism, for example to vary a distance between the flame and the hot surface of the TEG module (e.g., so as to accommodate heat sources of different heights) and/or to accommodate placement of the apparatus 700 on uneven terrain. The adjustment mechanism may be a plurality of adjustable or leveling feet with a threaded portion attached to the bottom of each leg. In other examples, removable shims may be used. Any other suitable adjustment mechanism may be used. The apparatus 700 may further include a wind screen disposed vertically along the length of the support structure to shield the flame of the heat source from debris and/or air movement.

The heat sink reservoir 732 may be attached directly to the cold surface of the TEG module. The heat sink reservoir 732 may be attached to the TEG module in any manner which minimizes thermal resistance between the TEG module and heat sink component. For example, the TEG module and heat sink reservoir 52 may be attached using a thermally conductive adhesive 53. As described herein, during use, the heat sink reservoir 732 may be filled with a heat transfer medium, salon referred to herein as heat sink fluid. The heat sink reservoir 732 may be attached to the TEG module in any manner which minimizes thermal resistance between the TEG module and heat sink component. For example, the TEG module and heat sink reservoir 52 may be attached using a thermally conductive adhesive 53. The heat transfer medium may be water, which may be generally inexpensive and readily available. In some examples, the heat sink fluid may be in direct physical contact with the cold surface of the TEG module. In such examples, the bottom wall of the reservoir may include one or more apertures through which the heat sink fluid can pass to contact the cold surface of the TEG module.

A kit can be provided that includes a container or package (not shown) for carrying the apparatus 700 and the dedicated heat source inside. As discussed above, the dedicated heat source may be, without being limited to, a candle, an alcohol burner, a hexamine-fuel-based heat source, an oil candle, or a jellied alcohol burner.

In one embodiment of the invention, a hand-held apparatus for use with a heat source and a liquid to generate electrical energy for an electrical device is provided, and can include a reservoir adapted to hold the liquid, a thermoelectric generator having first and second surfaces, the thermoelectric generator joined to the reservoir so that liquid in the reservoir engages the second surface of the thermoelectric generator, a thermally-conductive element engageable with the first surface of the thermoelectric generator for transferring heat from the heat source to the first surface, and a cable extending from the thermoelectric generator and having a connector for coupling to the electrical device whereby the thermoelectric generator generates electric energy that is delivered by the cable to the electrical device.

The apparatus can further include a retainer for permitting removable engagement of the thermally-conductive element with the first surface of the thermoelectric generator. The connector can include a USB connector.

In one embodiment of the invention, a hand-held apparatus for use with a heat source to generate electrical energy for an electrical device is provided, and can include a thermoelectric generator having first and second surfaces, a heat sink joined to the second surface of the thermoelectric generator for providing cooling to the second surface, a thermally-conductive element for receiving heat from the heat source, a retainer for permitting removable engagement of the thermally-conductive element with the first surface of the thermoelectric generator, and a cable extending from the thermoelectric generator and having a connector for coupling to the electrical device whereby the thermoelectric generator generates electric energy that is delivered by the cable to the electrical device.

The thermally-conductive element can be a strip of metal. The strip can include a first portion and a second portion extending orthogonal to the first portion, the first portion have a length and the second portion having a length different from the length of the first portion. The retainer can include a socket or cavity for receiving a portion of the strip and includes a retainer element for urging the portion against the second surface of the thermoelectric element. The element can include a spring. The heat sink can be a reservoir for holding a liquid.

In one embodiment of the invention, a portable apparatus for use with a heat source and a liquid to generate electrical energy for an electrical device is provided, and can include a heat sink adapted to hold the liquid, a thermoelectric generator having first and second sides, the second side of the thermoelectric generator in contact with the heat sink, a thermally-conductive element in direct contact with the first side of the thermoelectric generator for transferring heat from the heat source to the first side of the thermoelectric generator and generating electricity due to heat passing through the thermoelectric generator from the first to the second side, and a cable extending from the thermoelectric generator and having a connector for coupling to the electrical device for delivering electricity generated by the thermoelectric generator to the electrical device.

The thermally-conductive element can be a metallic plate. The thermally-conductive element can extend forwardly of the thermoelectric generator.

In one embodiment of the invention, a portable apparatus for use with a heat source to generate electrical energy for an electrical device is provided, and includes a support structure, a thermoelectric generator carried by the support structure and having first and second sides, a heat sink carried by the support structure, the second side of the thermoelectric generator in contact with the heat sink, at least one photovoltaic cell carried by the support structure and a cable coupled to at least one of the thermoelectric generator and the at least one photovoltaic cell and having a connector for coupling to the electrical device for delivering electricity generated by the at least one of the thermoelectric generator and the at least one photovoltaic cell to the electrical device.

The apparatus of can be used with a liquid, and the heat sink can be adapted to hold the liquid. The apparatus can further include a thermally-conductive element in direct contact with the first side of the thermoelectric generator for transferring heat from the heat source to the first side of the thermoelectric generator. The cable can be coupled to both the thermoelectric generator and the at least one photovoltaic cell.

In one embodiment of the invention, a portable apparatus for use with a heat source to generate electrical energy for an electrical device is provided, and can include a support structure, a thermoelectric generator carried by the support structure and having first and second sides, a heat sink carried by the support structure and in contact with the second side of the thermoelectric generator, and a cable coupled to the thermoelectric generator and having a connector for coupling to the electrical device for delivering electricity generated by the thermoelectric generator to the electrical device, the heat sink movable from a low-profile configuration for storage and an expanded configuration for operation.

The apparatus can be used with a liquid, and the heat sink can be a reservoir adapted to hold a liquid. The reservoir can be formed at least in part by a flexible plastic material that movable from a contracted configuration for storage and an expanded configuration for operation. The plastic material can have an accordion configuration.

In one embodiment of the invention, a portable apparatus for use on a horizontal surface with a heat source to generate electrical energy for an electrical device, comprising a support structure, a thermoelectric generator carried by the support structure and having top and bottom sides, a heat sink carried by the support structure and in contact with the top side of the thermoelectric generator, and a cable coupled to the thermoelectric generator and having a connector for coupling to the electrical device for delivering electricity generated by the thermoelectric generator to the electrical device, the support structure being configurable for movement from a low-profile configuration for storage and an expanded configuration for positioning the thermoelectric generator in an elevated position relative to the heat source.

The support structure can include a leg assembly configurable for movement from a contracted configuration for storage and an expanded configuration for positioning the thermoelectric generator in an elevated position relative to the heat source. The apparatus can be used with a liquid, and the heat sink can be adapted to hold the liquid. The apparatus can further include a thermally-conductive element in direct contact with the first side of the thermoelectric generator for transferring heat from the heat source to the first side of the thermoelectric generator.

In one embodiment of the invention, a portable apparatus for use on a horizontal surface with a heat source to generate electrical energy for an electrical device is provided, and includes a thermoelectric generator having top and bottom sides, a heat sink connected to the top side of the thermoelectric generator, and a stand for carrying the thermoelectric generator above the horizontal surface, and a cable coupled to the thermoelectric generator and having a connector for coupling to the electrical device for delivering electricity generated by the thermoelectric generator to the electrical device, whereby the thermoelectric generator can be positioned by the stand above the heat source during operation.

The stand can be removably coupleable to the thermoelectric generator.

In one embodiment of the invention, a hand-held apparatus for use with a heat source to generate electrical energy for an electrical device is provided, and includes a thermoelectric generator having first and second surfaces, a heat sink joined to the second surface of the thermoelectric generator for providing cooling to the second surface, a thermally-conductive element for receiving heat from the heat source engaging the first surface of the thermoelectric generator, the thermally-conductive element having a portion adapted to extend over the heat source and being provided with a plurality of apertures for facilitating travel of heat through the portion, and a cable extending from the thermoelectric generator and having a connector for coupling to the electrical device whereby the thermoelectric generator generates electric energy that is delivered by the cable to the electrical device.

The apertures can be selected from the group consisting of holes and slits. The apparatus can be used with a liquid, and the heat sink can be a reservoir adapted to hold a liquid. The reservoir can be formed at least in part by a flexible plastic material that movable from a contracted configuration for storage and an expanded configuration for operation.

This detailed description is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

1. The apparatus of claim 10, wherein the heat sink is a reservoir, the thermoelectric generator joined to the reservoir so that liquid in the reservoir engages the second side of the thermoelectric generator.

2. The apparatus of claim 10, further comprising a retainer for permitting removable contact of the thermally-conductive element with the first side of the thermoelectric generator.

3. The apparatus of claim 10, wherein the connector includes a USB connector.

4-9. (canceled)

10. A portable apparatus for use with a heat source and a liquid to generate electrical energy for an electrical device, comprising a heat sink adapted to hold the liquid, a thermoelectric generator having first and second sides, the second side of the thermoelectric generator in contact with the heat sink, a thermally-conductive element in direct contact with the first side of the thermoelectric generator for transferring heat from the heat source to the first side of the thermoelectric generator and generating electricity due to heat passing through the thermoelectric generator from the first to the second side, and a cable extending from the thermoelectric generator and having a connector for coupling to the electrical device for delivering electricity generated by the thermoelectric generator to the electrical device.

11. The apparatus of claim 10, wherein the thermally-conductive element is a metallic plate.

12. The apparatus of claim 10, wherein the thermally-conductive element extends forwardly of the thermoelectric generator.

13-16. (canceled)

17. A portable apparatus for use with a heat source to generate electrical energy for an electrical device, comprising a support structure, a thermoelectric generator carried by the support structure and having first and second sides, a heat sink carried by the support structure and in contact with the second side of the thermoelectric generator, and a cable coupled to the thermoelectric generator and having a connector for coupling to the electrical device for delivering electricity generated by the thermoelectric generator to the electrical device, the heat sink movable from a low-profile configuration for storage and an expanded configuration for operation.

18. The apparatus of claim 17 for use with a liquid, wherein the heat sink is a reservoir adapted to hold a liquid.

19. The apparatus of claim 18, wherein the reservoir is formed at least in part by a flexible plastic material that movable from a contracted configuration for storage and an expanded configuration for operation.

20. The apparatus of claim 19, wherein the plastic material has an accordion configuration.

21. A portable apparatus for use on a horizontal surface with a heat source to generate electrical energy for an electrical device, comprising a support structure, a thermoelectric generator carried by the support structure and having top and bottom sides, a heat sink carried by the support structure and in contact with the top side of the thermoelectric generator, and a cable coupled to the thermoelectric generator and having a connector for coupling to the electrical device for delivering electricity generated by the thermoelectric generator to the electrical device, the support structure being configurable for movement from a low-profile configuration for storage and an expanded configuration for positioning the thermoelectric generator in an elevated position relative to the heat source.

22. The apparatus of claim 21, wherein the support structure includes a leg assembly configurable for movement from a contracted configuration for storage and an expanded configuration for positioning the thermoelectric generator in an elevated position relative to the heat source.

23. The apparatus of claim 21 for use with a liquid, wherein the heat sink is adapted to hold the liquid.

24. The apparatus of claim 21, further comprising a thermally-conductive element in direct contact with the first side of the thermoelectric generator for transferring heat from the heat source to the first side of the thermoelectric generator.

25-26. (canceled)

27. The apparatus of claim 10, wherein the thermally-conductive element has a portion adapted to extend over the heat source that is provided with a plurality of apertures for facilitating travel of heat through the portion.

28. The apparatus of claim 27, wherein the apertures are selected from the group consisting of holes and slits.

29-30. (canceled)
